(19) United States
(12) Patent Application Publication
(10) Pub. No.: US 2025/0324896 A1
(43) Pub. Date: Oct. 16, 2025

(54) DISPLAY DEVICE

(71) Applicant: SAMSUNG DISPLAY CO., LTD., YONGIN-SI (KR)

(72) Inventors: KANG MOON JO, YONGIN-SI (KR); SUN KWANG KIM, YONGIN-SI (KR); DONG YOON LEE, YONGIN-SI (KR); SEONG YOUNG LEE, YONGIN-SI (KR)

(21) Appl. No.: 19/010,362

(22) Filed: Jan. 6, 2025

(30) Foreign Application Priority Data
Apr. 16, 2024 (KR) 10-2024-0050427

(51) Int. Cl. H10K 59/80; H10K 59/122

(52) U.S. Cl. CPC H10K 59/8792; H10K 59/122

(57) ABSTRACT

A display device includes, a substrate, and a light emitting element disposed on the substrate. The light emitting element includes first to third emission areas spaced apart from one another. The first emission area includes a first portion overlapping the third emission area in a first direction, and a second portion overlapping the second emission area in the first direction. The second emission area includes a third portion overlapping the third emission area in a second direction different from the first direction, and a fourth portion overlapping the first emission area in the second direction. A first side of the second portion and a second side of the fourth portion extend in a third direction different from the first direction and the second direction.

### CROSS-REFERENCE TO RELATED APPLICATION

This patent application claims priority under 35 U.S.C. 119 to Korean Patent Application No. 10-2024-0050427 filed on Apr. 16, 2024, in the Korean Intellectual Property Office, the disclosure of which is incorporated by reference in its entirety herein.

### 1. Technical Field

The present disclosure is directed to a display device and a method of manufacturing the display device.

### 2. Discussion of Related Art

The importance of display devices has steadily increased with the development of multimedia technology. Along with this trend, various types of display devices such as a liquid crystal display (LCD) device, an organic light emitting diode (OLED) display device and the like have been developed.

Among the display devices, a self-light emitting display device includes a self-light emitting element such as an organic light emitting layer. The self-light emitting element may include a light emitting layer interposed between two electrodes. In the case of using the organic light emitting element as the self-light emitting element, electrons and holes from the two electrodes are recombined in the light emitting layer to produce excitons, which transition from an excited state to a ground state to emit light.

The self-light emitting display device is attracting attention as a next-generation display device because of its ability to meet high display quality requirements such as wide viewing angle, high brightness and contrast, and quick response speed as well as its ability to have a low power consumption, a light weight, and thinness due to no necessity of a backlight unit.

During the manufacture of a self-light emitting display device, materials such as conductive inks or organic light-emitting diode (OLED) materials are often printed on specific areas of a substrate. The ink landing margin ensures that these materials are deposited accurately, avoiding overflow into unintended areas, which could affect the performance or appearance of a display of the self-light emitting display device.

As high-resolution display devices gradually emerge, the size of individual pixels is becoming smaller. Accordingly, it becomes more difficult to secure the ink landing margin and to prevent color mixing between adjacent pixels.

### SUMMARY

Example embodiments of the present disclosure may provide a display device that secures an ink landing margin with a high-resolution pixel structure.

Example embodiments of the present disclosure may also provide a display device that secures a width of a light blocking area with a high-resolution pixel structure.

Example embodiments of the present disclosure may also provide a display device in which color mixing between adjacent pixels or adjacent unit pixels is prevented.

According to an embodiment of the present disclosure, there is provided a display device including a substrate and a light emitting element disposed on the substrate. The light emitting element includes first to third emission areas spaced apart from one another. The first emission area includes a first portion overlapping the third emission area in a first direction, and a second portion overlapping the second emission area in the first direction. The second emission area includes a third portion overlapping the third emission area in a second direction different from the first direction, and a fourth portion overlapping the first emission area in the second direction. A first side of the second portion and a second side of the fourth portion extend in a third direction different from the first direction and the second direction.

In an embodiment, the first portion includes a third side facing the third emission area, the third portion comprises a fourth side facing the third emission area, the third side extends in the second direction, and the fourth side extends in the first direction.

In an embodiment, the third emission area includes a fifth side opposing the third side, and a sixth side opposing the fourth side, and the fifth side extends in the second direction, and the sixth side extends in the first direction.

In an embodiment, an angle formed by the first side and the third side is an obtuse angle, an angle formed by the second side and the fourth side is an obtuse angle, and an angle formed by the fifth side and the sixth side is a right angle.

In an embodiment, a length of the third side in the second direction is longer than a length of the fifth side in the second direction.

In an embodiment, a length of the fourth side in the first direction is longer than a length of the sixth side in the first direction.

In an embodiment, the first emission area and the second emission area have a trapezoidal shape, and the third emission area has a rectangular shape.

In an embodiment, the first portion and the third portion have a rectangular shape, and the second portion and the fourth portion have a triangular shape.

In an embodiment, the first to third emission areas respectively comprise first to third vertices located at positions at which the first to third emission areas face each other, and with respect to a first reference line extending in the third direction from a center of a reference circle passing through the first to third vertices, the first emission area and the second emission area are spaced apart by the same distance.

In an embodiment, a distance between the first emission area and a second reference line extending in the second direction from the center of the reference circle is greater than a distance between the second reference line and the third emission area.

In an embodiment, a distance between the second emission area and a third reference line extending in the first direction from the center of the reference circle and is greater than a distance between the third reference line and the third emission area.

In an embodiment, the display device may further include a pixel defining film having an opening defining the first to third emission areas, wherein the light emitting element includes a light emitting layer disposed in the opening, and the light emitting layer contains an ink material.

In an embodiment, a width of a landing area of the ink material is smaller than or equal to a width of each of the first to third emission areas.

In an embodiment, the display device may further comprise, a plurality of color filters disposed on the light emitting element, and overlapping the first to third emission areas, and a light transmitting layer disposed between the light emitting element and the color filter, overlapping the first to third emission areas, and containing a light scatterer.

According to an embodiment of the present disclosure, there is provided a display device including a first unit pixel and a second unit pixel, wherein each of the first unit pixel and the second unit pixel includes, first to third emission areas including a light emitting element and spaced apart from each other, and a light blocking area surrounding the first to third emission areas, wherein the first emission area includes a first portion overlapping the third emission area in a first direction, and a second portion overlapping the second emission area in the first direction, the second emission area includes a third portion overlapping the third emission area in a second direction different from the first direction, and a fourth portion overlapping the first emission area in the second direction, and a first light blocking area located between the second portion and the fourth portion extends in a third direction different from the first direction and the second direction.

In an embodiment, a second light blocking area located between the first portion and the third emission area extends in the second direction, and a third light blocking area located between the third portion and the third emission area extends in the first direction.

In an embodiment, an angle formed by an extension direction of the first light blocking area and an extension direction of the second light blocking area is an obtuse angle, an angle formed by the extension direction of the first light blocking area and an extension direction of the third light blocking area is an obtuse angle, and an angle formed by the extension direction of the second light blocking area and the extension direction of the third light blocking area is a right angle.

In an embodiment, the first to third emission areas respectively comprise first to third vertices located at positions at which the first to third emission areas face each other, and with respect to a first reference line extending in the third direction from a center of a reference circle passing through the first to third vertices, a width of one area of the first light blocking area and a width of another area of the first light blocking area are the same.

In an embodiment, with respect to a second reference line extending in the second direction from the center of the reference circle, a width of one area of the second light blocking area is greater than a width of another area of the second light blocking area.

In an embodiment, with respect to a first reference line extending in the first direction from the center of the reference circle, a width of one area of the third light blocking area is greater than a width of the other area of the third light blocking area.

In an embodiment, the display device may further include a third unit pixel, wherein the second unit pixel is disposed on one side of the first unit pixel in the first direction, the third unit pixel is disposed on one side of the first unit pixel in the second direction, and a width of a fourth emission area located between the second emission area and the third emission area of the first unit pixel and the first emission area of the second unit pixel is equal to a width of a fifth light blocking area located between the first emission area and the third emission area of the first unit pixel and the second emission area of the third unit pixel.

In an embodiment, the first to fifth light blocking areas have the same width.

In an embodiment, the first emission area and the second emission area have a trapezoidal shape, and the third emission area has a rectangular shape.

In an embodiment, the first portion and the third portion have a rectangular shape, and the second portion and the fourth portion have a triangular shape.

According to an embodiment of the present disclosure, there is provided a display device including first to third emission areas spaced apart from each other. The first emission area includes a first side facing the second emission area, a second side facing the third emission area, a third side opposing the first side, and a fourth side opposing the second side. The second emission area includes a fifth side facing the first emission area, a sixth side facing the third emission area, a seventh side opposing the fifth side, and an eighth side opposing the sixth side. The third emission area includes a ninth side opposing the second side, a tenth side opposing the sixth side, an eleventh side opposing the ninth side, and a twelfth side opposing the tenth side, the third side, the sixth side, the eighth side, the tenth side, and the twelfth side extend in a first direction, the second side, the fourth side, the seventh side, the ninth side, and the eleventh side extend in a second direction different from the first direction, and the first side and the fifth side extend in a third direction different from the first direction and the second direction.

In an embodiment, the first emission area comprises a first chamfered side located between the first side and the fourth side, and the second emission area comprises a second chamfered side located between the fifth side and the eighth side.

In an embodiment, the first chamfered side extends in the first direction, and the second chamfered side extends in the second direction.

In an embodiment, the first chamfered side and the second chamfered side extend in a direction different from the first to third directions.

In an embodiment, the first emission area comprises a third chamfered side located between the third side and the fourth side, the second emission area comprises a fourth chamfered side located between the seventh side and the eighth side, and the third emission area comprises a fifth chamfered side located between the eleventh side and the twelfth side.

In an embodiment, the first emission area comprises a third chamfered side located between the third side and the fourth side, the second emission area comprises a fourth chamfered side located between the seventh side and the eighth side, and the third emission area comprises a fifth chamfered side located between the eleventh side and the twelfth side.

In an embodiment, an extension direction of the fifth chamfered side is different from extension directions of the third chamfered side and the fourth chamfered side.

In an embodiment, the third chamfered side and the fourth chamfered side extend in the third direction.

In an embodiment, the third to fifth chamfered sides extend in a direction different from the first to third directions.

In the display device according to an embodiment of the present disclosure, it is possible to secure an ink landing margin with a high-resolution pixel structure.

In the display device according to an embodiment of the present disclosure, it is possible to secure a width of a light blocking area with a high-resolution pixel structure.

In the display device according to an embodiment of the present disclosure, it is possible to prevent color mixing between adjacent pixels or adjacent unit pixels.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic perspective view showing a display device according to an embodiment;

FIG. 2 is a schematic cross-sectional view of the display device taken along line X1-X1′ of FIG. 1;

FIG. 3 is a schematic plan view illustrating a display substrate of the display device and other components according to an embodiment;

FIG. 4 is a diagram illustrating pixels and lines of the display device according to an embodiment;

FIG. 5 is a plan view schematically illustrating emission areas of a display substrate of the display device according to an embodiment;

FIG. 6 is a plan view schematically illustrating light exit areas of a color conversion substrate of the display device according to an embodiment;

FIG. 7 is a cross-sectional view of a display device according to an embodiment taken along line X2-X2′ of FIGS. 5 and 6;

FIG. 8 is a cross-sectional view of a display device according to an embodiment;

FIG. 9 is a circuit diagram illustrating a pixel circuit and a wiring connected to the pixel circuit of a display device according to an embodiment;

FIG. 10 is a plan view showing disposition of emission areas included in unit pixels according to an embodiment;

FIG. 11 is a plan view illustrating a process in which ink is ejected into an emission area to form a light emitting layer according to an embodiment;

FIG. 12 is a plan view showing disposition of emission areas included in unit pixels according to an embodiment;

FIG. 13 is a plan view showing disposition of emission areas included in unit pixels according to an embodiment;

FIG. 14 is a plan view showing disposition of emission areas included in unit pixels according to an embodiment; and

FIG. 15 is a plan view showing disposition of emission areas included in unit pixels according to an embodiment.

### DETAILED DESCRIPTION

The invention will now be described more fully hereinafter with reference to the accompanying drawings, in which example embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in detail with reference to the accompanying drawings.

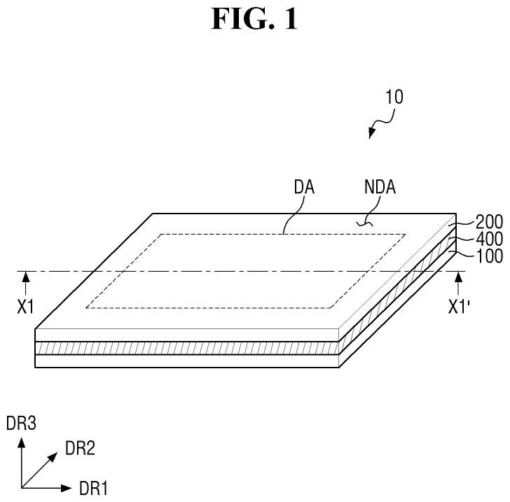

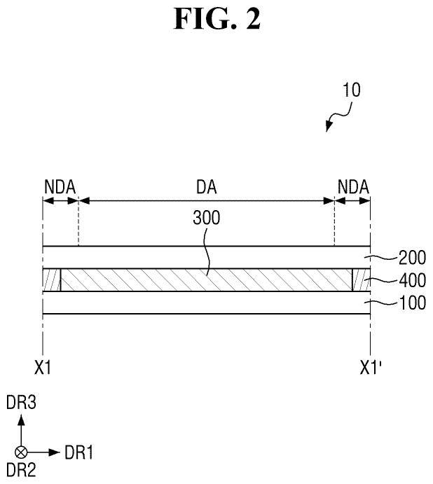

FIG. 1 is a schematic perspective view showing a display device according to an embodiment. FIG. 2 is a schematic cross-sectional view of the display device taken along line X1-X1′ of FIG. 1.

Referring to FIGS. 1 and 2, a display device 10 may be applied to a variety of electronic apparatuses, i.e., small and medium electronic devices such as a tablet personal computer (PC), a smartphone, a car navigation unit, a camera, a center information display (CID) provided in a vehicle, a wristwatch-type electronic device, a personal digital assistant (PDA), a portable multimedia player (PMP) and a game console, and medium and large electronic devices such as a television, an external billboard, a monitor, a personal computer and a laptop computer. The display device 1 may also be applied to other electronic devices without departing from the present disclosure.

In an embodiment, the display device 10 has a rectangular shape in a plan view. For example, the display device 10 may include two long sides extending in a first direction DR1 and two short sides extending in a second direction DR2 intersecting the first direction DR1. A corner where the long side and the short side of the display device 10 meet may have a right angle. However, the present disclosure is not limited thereto, and the corner may have a curved surface. In another embodiment, the long side may extend in the second direction DR2, and the short side may extend in the first direction DR1. However, the planar shape of the display device 10 is not limited to the exemplified one, but may have a circular shape or other shapes.

In FIG. 1 and FIG. 2, the first direction DR1 and the second direction DR2 cross each other as horizontal directions. For example, the first direction DR1 and the second direction DR2 may be orthogonal to each other. In addition, a third direction DR3 crosses the first direction DR1 and the second direction DR2, and may be, for example, perpendicular directions orthogonal to each other. Unless otherwise defined, in the present specification, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display device 10 may include a display area DA for displaying an image and a non-display area NDA for not displaying an image. In an embodiment, the non-display area NDA is located around the display area DA and may surround the display area DA.

In an embodiment, the display device 10 includes a display substrate 100 having stacked structure and a color conversion substrate 200 facing the display substrate 100. The display device 10 may further include a scaling portion 400 for coupling the display substrate 100 and the color conversion substrate 200, and a filler 300 filled between the display substrate 100 and the color conversion substrate 200.

The display substrate 100 may include elements and circuits for displaying an image, for example, a pixel circuit such as a switching element, a pixel defining film and a self-light emitting element that defines an emission area and a non-emission area, which will be described later, in the display area DA. In an embodiment, the self-light emitting element may include at least one of an organic light emitting diode, a quantum dot light emitting diode, an inorganic micro light emitting diode (e.g., micro LED), or an inorganic nano light emitting diode (e.g., nano LED). Hereinafter, for simplicity of description, a case where the self-light emitting element is an organic light emitting element will be described as an example.

The color conversion substrate 200 may be disposed above and facing the display substrate 100. In an embodiment, the color conversion substrate 200 includes a color conversion pattern for converting the color of incident light. In an embodiment, the color conversion pattern 200 includes at least one of a color filter and a wavelength conversion pattern.

The sealing portion 400 may be positioned between the display substrate 100 and the color conversion substrate 200 in the non-display area NDA. The sealing portion 400 may be disposed along edges of the display substrate 100 and the color conversion substrate 200 in the non-display area NDA to surround the display area DA in a plan view. The display substrate 100 and the color conversion substrate 200 may be bonded to each other through the sealing portion 400.

In an embodiment, the scaling portion 400 is made of an organic material. For example, the sealing portion 400 may be made of an epoxy-based resin, but is not limited thereto.

The filler 300 may be positioned in a space surrounded by the scaling portion 400 between the display substrate 100 and the color conversion substrate 200. The filler 300 may fill the space between the display substrate 100 and the color conversion substrate 200.

In an embodiment, the filler 300 is made of a material that can transmit light. In an embodiment, the filler 300 is made of an organic material. For example, the filler 300 may be formed of a silicon-based organic material, an epoxy-based organic material, or the like, but is not limited thereto. In another embodiment, the filler 300 is omitted. For example, when the filler 300 is omitted, an air gap or a gap filled with another gas may be present in that region.

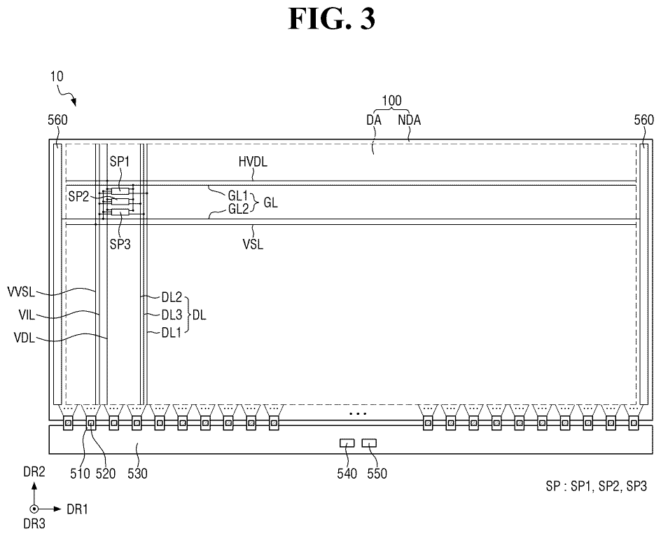

FIG. 3 is a schematic plan view illustrating the display substrate and other components according to an embodiment.

Referring to FIG. 3, the display device 10 includes the display substrate 100, a flexible film 510, a display driver 520 (e.g., a first driver circuit), a circuit board 530, a timing controller 540 (e.g., a controller circuit), a power supply unit 550 (e.g., a power supply), and a gate driver 560 (e.g., a second driver circuit).

The display substrate 100 may have a rectangular shape in a plan view. For example, the display substrate 100 may have a rectangular shape, in a plan view, having a long side in the first direction DR1 and a short side in the second direction DR2. A corner where the long side in the first direction DR1 and the short side in the second direction DR2 meet may be right-angled or rounded with a predetermined curvature. However, the planar shape of the display substrate 100 is not limited to the rectangular shape, and may be formed in another polygonal shape, a circular shape or an elliptical shape. For example, the display substrate 100 may be formed to be flat, but is not limited thereto. In another example, the display substrate 100 may be bent with a predetermined curvature.

The display substrate 100 may include the display area DA and the non-display area NDA.

The display area DA, which is an area for displaying an image, may be defined as the central area of the display substrate 100. The display area DA may include a pixel SP, a gate line GL, a data line DL, an initialization voltage line VIL, a first voltage line VDL, a horizontal voltage line HVDL, and a vertical voltage line VVSL, and a second voltage line VSL. The pixel SP may be formed in each pixel area at intersections of the data lines DL and the gate lines GL. Each of the pixels SP may include first to third sub-pixels SP1, SP2, and SP3. Each of the first to third sub-pixels SP1, SP2, and SP3 may be connected to the gate line GL and the data line DL. Each of the first to third sub-pixels SP1, SP2, and SP3 may be defined as a minimum unit area that outputs light.

Each of the first to third sub-pixels SP1, SP2, and SP3 may include an organic light emitting diode (OLED) having an organic light emitting layer, a quantum dot light emitting diode (LED) including a quantum dot light emitting layer, a micro LED, or an inorganic LED having an inorganic semiconductor.

The first sub-pixel SP1 may emit light of a first color such as red light, the second sub-pixel SP2 may emit light of a second color such as green light, and the third sub-pixel SP3 may emit light of a third color such as blue light.

The gate line GL may include the first gate line GL1 and the second gate line GL2. The first gate lines GL1 may extend in the first direction DR1 and may be spaced apart from each other in the second direction DR2. The first gate line GL1 may receive a first gate signal from the gate driver 560 and supply the first gate signal to the first to third sub-pixels SP1, SP2, and SP3.

The second gate lines GL2 may extend in the first direction DR1 and may be spaced apart from each other in the second direction DR2. The second gate line GL2 may receive a second gate signal from the gate driver 560 and supply the second gate signal to the first to third sub-pixels SP1, SP2, and SP3.

The data lines DL may extend in the second direction DR2 and may be spaced apart from each other in the first direction DR1. The data lines DL may include first to third data lines DL1, DL2, and DL3. Each of the first to third data lines DL1, DL2, and DL3 may supply a data voltage to each of the first to third sub-pixels SP1, SP2, and SP3.

The initialization voltage lines VIL may extend in the second direction DR2 and may be spaced apart from each other in the first direction DR1. The initialization voltage line VIL may supply the initialization voltage received from the display driver 520 to the pixel circuit of each of the first to third sub-pixels SP1, SP2 and SP3. The initialization voltage line VIL may receive a sensing signal from the pixel circuit of each of the first to third sub-pixels SP1, SP2 and SP3 to supply the sensing signal to the display driver 520.

The first voltage lines VDL may extend in the second direction DR2 and may be spaced apart from each other in the first direction DR1. The first voltage line VDL may supply a driving voltage or a high potential voltage received from the power supply unit 550 to the first to third sub-pixels SP1, SP2, and SP3.

The horizontal voltage lines HVDL may extend in the first direction DR1 and may be spaced apart from each other in the second direction DR2. The horizontal voltage line HVDL may be connected to the first voltage line VDL. The horizontal voltage line HVDL may receive a driving voltage or a high potential voltage from the first voltage line VDL.

The vertical voltage lines VVSL may extend in the second direction DR2 and may be spaced apart from each other in the first direction DR1. The vertical voltage line VVSL may be connected to the second voltage line VSL. The vertical voltage line VVSL may supply a low potential voltage received from the power supply unit 550 to the second voltage line VSL.

The second voltage lines VSL may extend in the first direction DR1 and may be spaced apart from each other in the second direction DR2. The second voltage line VSL may supply a low potential voltage to the first to third sub-pixels SP1, SP2, and SP3.

The connection relationship of the pixel SP, the gate line GL, the data line DL, the initialization voltage line VIL, the first voltage line VDL, the horizontal voltage line HVDL, the vertical voltage line VVSL, and the second voltage line VSL may be designed and changed according to the number and arrangement of the pixels SP.

The non-display area NDA may be defined as the remaining area of the display substrate 100 except the display area DA. For example, the non-display area NDA may include fan-out lines connecting the data line DL, the initialization voltage line VIL, the first voltage line VDL, and the vertical voltage line VVSL to the display driver 520, the gate driver 560, and a pad portion connected to the flexible film 510.

The flexible film 510 may be connected to the pad portion disposed below the non-display area NDA. Input terminals provided on one side of the flexible film 510 may be attached to the circuit board 530 by a film attaching process, and output terminals provided at the other side of the flexible film 510 may be attached to the pad portion by the film attaching process. For example, the flexible film 510 may be bent like a tape carrier package or a chip on film. The flexible film 510 may be bent toward the lower portion of the display substrate 100 to reduce a bezel area of the display device 10.

The display driver 520 may be mounted on the flexible film 510. For example, the display driver 520 may be implemented as an integrated circuit (IC). The display driver 520 may receive digital video data and a data control signal from the timing controller 540, and according to the data control signal, convert the digital video data to an analog data voltage to supply it to the data lines DL through the fan-out lines.

The circuit board 530 may support the timing controller 540 and the power supply unit 550, and supply signals and power to the display driver 520. For example, the circuit board 530 may supply a signal supplied from the timing controller 540 and a power voltage supplied from the power supply unit 550 to the flexible film 510 and the display driver 520 to display an image on each pixel. A signal line for the signal and a power line for the power voltage may be disposed on the circuit board 530.

The timing controller 540 may be mounted on the circuit board 530 and receive image data and a timing synchronization signal supplied from the display driving system or a graphic device through a user connector provided on the circuit board 530. The timing controller 540 may generate digital video data by arranging the image data to fit the pixel arrangement structure based on the timing synchronization signal, and may supply the generated digital video data to the display driver 520. The timing controller 540 may generate the data control signal and the gate control signal based on the timing synchronization signal. The timing controller 540 may control the data voltage supply timing of the display driver 520 based on the data control signal, and may control the gate signal supply timing of the gate driver 560 based on the gate control signal.

The power supply unit 550 may be disposed on the circuit board 530 to supply a power voltage to the flexible film 510 and the display driver 520. For example, the power supply unit 550 may generate a driving voltage or a high potential voltage and supply it to the first voltage line VDL, may generate a low potential voltage and supply it to the vertical voltage line VVSL, and may generate an initialization voltage and supply it to the initialization voltage line VIL.

The gate driver 560 may be disposed on the left and right sides of the non-display area NDA. For example, the gate driver 560 may include a first gate driving circuit disposed to the left of the non-display area NDA and a second gate driving circuit disposed to the right of the non-display area NDA. The gate driver 560 may generate a gate signal based on the gate control signal supplied from the timing controller 540. The gate control signal may include a start signal, a clock signal, and a power voltage, but the present disclosure is not limited thereto. The gate driver 560 may supply a gate signal to the gate line GL according to a set order.

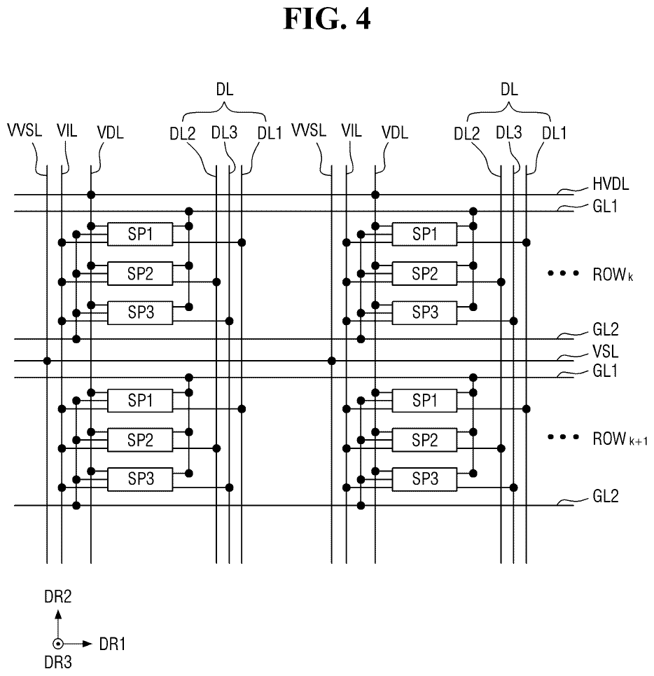

FIG. 4 is a diagram illustrating pixels and lines of the display device according to an embodiment.

Referring to FIG. 4 in addition to FIG. 3, the pixels SP may include first to third sub-pixels SP1, SP2, and SP3. The pixel circuits of the first sub-pixel SP1, the second sub-pixel SP2, and the third pixel SP3 may be arranged in the opposite direction of the second direction DR2, but the arrangement direction of the pixel circuits is not limited thereto.

Each of the first to third sub-pixels SP1, SP2, and SP3 may be connected to the first voltage line VDL, the initialization voltage line VIL, the gate line GL, and the data line DL.

The first voltage line VDL may extend in the second direction DR2. The first voltage line VDL may be disposed on the left side of the pixel circuits of the first to third sub-pixels SP1, SP2 and SP3. The first voltage line VDL may supply a driving voltage or high potential voltage to a transistor of each of the first to third sub-pixels SP1, SP2 and SP3.

The horizontal voltage line HVDL may extend in the first direction DR1. The horizontal voltage line HVDL may be disposed above the first gate line GL1 disposed in a k^{th} row ROWₖ (k being a positive integer). The horizontal voltage line HVDL may be connected to the first voltage line VDL. The horizontal voltage line HVDL may receive a driving voltage or a high potential voltage from the first voltage line VDL.

The initialization voltage line VIL may extend in the second direction DR2. The initialization voltage line VIL may be disposed on the left side of the auxiliary line of the second gate line GL2, which is branched in the second direction DR2. The initialization voltage line VIL may be disposed between the auxiliary line of the second gate line GL2, which is branched in the second direction DR2, and the vertical voltage line VVSL. The initialization voltage line VIL may supply an initialization voltage to the pixel circuit of each of the first to third sub-pixels SP1, SP2, and SP3. The initialization voltage line VIL may receive a sensing signal from the pixel circuit of each of the first to third sub-pixels SP1, SP2 and SP3 to supply the sensing signal to the display driver 520.

The vertical voltage line VVSL may extend in the second direction DR2. The vertical voltage line VVSL may be disposed on the left side of the initialization voltage line VIL. The vertical voltage line VVSL may be connected between the power supply unit 550 and the second voltage line VSL. The vertical voltage line VVSL may supply the low potential voltage supplied from the power supply unit 550 to the second voltage line VSL.

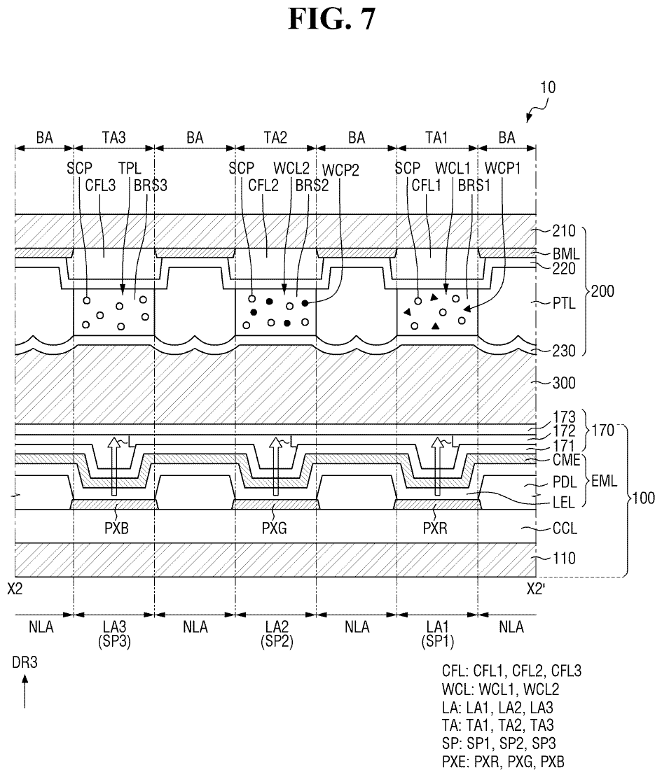

The second voltage line VSL may extend in the first direction DR1. The second voltage line VSL may be disposed above the first gate line GL1 disposed in a (k+1)^{th} row ROWₖ₊₁. The second voltage line VSL may supply the low potential voltage received from the vertical voltage line VVSL to a light emitting element layer EML (see FIG. 7) of the first to third sub-pixels SP1, SP2, and SP3.

The first gate line GL1 may extend in the first direction DR1. The first gate line GL1 may be disposed above the pixel circuit of the first pixel SP1. At least a part of the first gate line GL1 may extend in a direction opposite to the second direction DR2. For example, the first gate line GL1 may include an auxiliary line branched from the right sides of the first to third sub-pixels SP1, SP2, and SP3 and extending in the direction opposite to the second direction DR2. The auxiliary line of the first gate line GL1 may be disposed on the right sides of the pixel circuits of the first to third pixels SP1, SP2, and SP3. The first gate line GL1 may supply the first gate signal received from the gate driver 560 to the pixel circuits of the first to third sub-pixels SP1, SP2, and SP3 through the auxiliary line extending in the direction opposite to the second direction DR2.

The second gate line GL2 may extend in the first direction DR1. The second gate line GL2 may be disposed under the pixel circuit of the third pixel SP3. At least a part of the second gate line GL2 may extend in the second direction DR2. For example, the second gate line GL2 may include an auxiliary line branched from the left side of the first voltage line VDL and extending in the second direction DR2. The auxiliary line of the second gate line GL2 may be disposed on the left of the first voltage line VDL. The second gate line GL2 may supply the second gate signal received from the gate driver 560 to the pixel circuits of the first to third sub-pixels SP1, SP2, and SP3 through the auxiliary line extending in the second direction DR2.

The data lines DL may extend in the second direction DR2. The data lines DL may supply a data voltage to the pixel SP. The data lines DL may include first to third data lines DL1, DL2, and DL3.

The second data line DL2 may extend in the second direction DR2. The second data line DL2 may be disposed on the right side of the auxiliary line of the first gate line GL1. The second data line DL2 may supply the data voltage received from the display driver 520 to the pixel circuit of the second pixel SP2.

The third data line DL3 may extend in the second direction DR2. The third data line DL3 may be disposed on the right side of the second data line DL2. The third data line DL3 may supply the data voltage received from the display driver 520 to the pixel circuit of the third pixel SP3.

The first data line DL1 may extend in the second direction DR2. The first data line DL1 may be disposed on the right side of the third data line DL3. The first data line DL1 may supply the data voltage received from the display driver 520 to the pixel circuit of the first sub-pixel SP1.

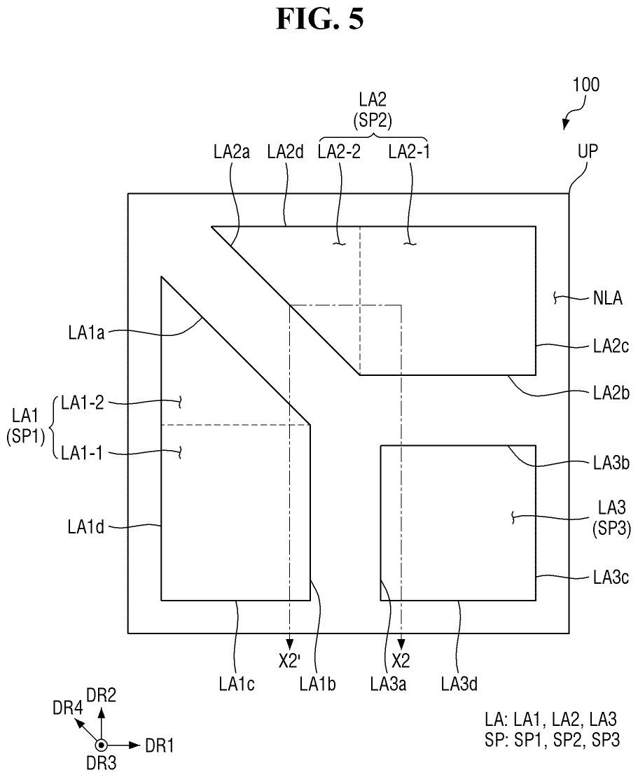

FIG. 5 is a plan view schematically illustrating emission areas of a display substrate according to an embodiment.

Referring to FIG. 5 in addition to FIGS. 1 and 2, the display substrate 100 may include a plurality of emission areas LA and a non-emission area NLA.

The plurality of emission areas LA may be areas in which a light emitting layer LEL (see FIG. 7) is exposed by an opening of a pixel defining film PDL (see FIG. 7), and the non-emission area NLA may be an area in which the pixel defining film PDL (see FIG. 7) is positioned. For example, the plurality of emission areas LA may be areas in which light generated from the light emitting elements of the display substrate 100 moves to the color conversion substrate 200, and the non-emission area NLA may be an area in which the light generated by the light emitting elements of the display substrate 100 does not move to the color conversion substrate 200. The boundary between the emission area LA and the non-emission area NLA may be defined by an opening of the pixel defining film PDL (see FIG. 7) to be described later and an outer wall surrounding the opening.

In an embodiment, the plurality of emission areas LA include a first emission area LA1, a second emission area LA2, and a third emission area LA3 that are spaced apart from each other.

The light emitted from the display substrate 100 to the color conversion substrate 200 in the plurality of emission areas LA may be light of a third color. In an embodiment, the light of the third color is blue light, and may have a peak wavelength within a range of about 440 nm to about 480 nm. The peak wavelength may refer to a wavelength at which the intensity of light is maximized within a wavelength range. However, the present disclosure is not limited thereto, and the light emitted from the display substrate 100 to the color conversion substrate 200 in the plurality of emission areas LA may be light in an ultraviolet region. Alternatively, the first to third emission areas LA1, LA2, and LA3 may emit red, green, and blue light, respectively.

The first emission area LA1, the second emission area LA2, and the third emission area LA3 may constitute the first sub-pixel SP1, the second sub-pixel SP2, and the third sub-pixel SP3, respectively. The first emission area LA1, the second emission area LA2, and the third emission area LA3 may constitute one unit pixel UP. The first emission area LA1, the second emission area LA2, and the third emission area LA3 may be repeatedly disposed along the first direction DR1 and the second direction DR2 across the entire display area DA in units of a plurality of unit pixels UP. The unit pixel UP may be a unit color pixel that represents one color by combining the colors expressed in the first to third sub-pixels SP1, SP2, and SP3.

Within the unit pixel UP, the first emission area LA1 may be generally disposed in the left area or lower left area and extend in the second direction DR2. Within the unit pixel UP, the second emission area LA2 may be generally disposed in the upper area or upper right area and extend in the first direction DR1. Within the unit pixel UP, the third emission area LA3 may be generally disposed in the lower right area.

For example, the unit pixel UP may include a first quadrant positioned on one side of the first direction DR1 and one side of the second direction DR2, a second quadrant positioned on the other side of the first direction DR1 and one side of the second direction DR2, a third quadrant positioned on the other side of the first direction DR1 and the other side of the second direction DR2, and a fourth quadrant positioned on one side of the first direction DR1 and the other side of the second direction DR2. The first emission area LA1 may be disposed across the second quadrant and the third quadrant, the second emission area LA2 may be disposed across the first quadrant and the second quadrant, and the third emission area LA3 may be disposed in the fourth quadrant.

The first emission area LA1 may overlap the second emission area LA2 and the third emission area LA3 in the first direction DR1. The second emission area LA2 may overlap the first emission area LA1 and the third emission area LA3 in the second direction DR2. The third emission area LA3 may overlap the first emission area LA1 in the first direction DR1 and may overlap the second emission area LA2 in the second direction DR2.

The widths (or lengths) and areas of the first to third emission areas LA1, LA2, and LA3 may be different. In an embodiment, the areas of the first emission area LA1 and the second emission area LA2 are larger than the area of the third emission area LA3. In an embodiment, the length of the first emission area LA1 in the second direction DR2 is longer than the length of the third emission area LA3 in the second direction DR2. In an embodiment, the length of the second emission area LA2 in the first direction DR1 is longer than the length of the third emission area LA3 in the first direction DR1.

In FIG. 5, although the area of the first emission area LA1 and the area of the second emission area LA2 are illustrated to be the same, the present disclosure is not limited thereto, and the area of the first emission area LA1 and the area of the second emission area LA2 may be different from each other. Although the width (or length) of the first emission area LA1 and the width (or length) of the second emission area LA2 are illustrated to be the same, the present disclosure is not limited thereto, and the width (or length) of the first emission area LA1 and the width (or length) of the second emission area LA2 may be different from each other.

The first to third emission areas LA1, LA2, and LA3 may have a polygonal shape. For example, the first emission area LA1 and the second emission area LA2 may have a trapezoidal shape, and the third emission area LA3 may have a rectangular (or square) shape.

The first emission area LA1 includes a first portion LA1-1 and a second portion LA1-2. The second emission area LA2 includes a third portion LA2-1 and a fourth portion LA2-2. The first portion LA1-1 and the second portion LA1-2 may be disposed side by side in the second direction DR2. The third portion LA2-1 and the fourth portion LA2-2 may be disposed side by side in the first direction DR1.

The first portion LA1-1 may overlap the third emission area LA3 in the first direction DR1, and the second portion LA1-2 may overlap the second emission area LA2 in the first direction DR1. The third portion LA2-1 may overlap the third emission area LA3 in the second direction DR2, and the fourth portion LA2-2 may overlap the first emission area LA1 in the second direction DR2.

The first portion LA1-1 may have a quadrilateral shape, the second portion LA1-2 may have a triangular shape, the third portion LA2-1 may have a quadrilateral shape, and the fourth portion LA2-2 may have a triangular shape.

The first emission area LA1 may include a first side LA1a facing the second emission area LA2, a second side LA1b facing the third emission area LA3, a third side LA1c opposing the first side LA1a, and a fourth side LA1d opposing the second side LA1b. The second emission area LA2 may include a fifth side LA2a facing the first emission area LA1, a sixth side LA2b facing the third emission area LA3, a seventh side LA2c opposing the fifth side LA2a, and an eighth side LA2d opposing the sixth side LA2b. The third emission area LA3 may include a ninth side LA3a opposing the second side LA1b, a tenth side LA3b opposing the sixth side LA2b, an eleventh side LA3c opposing the ninth side LA3a, and a twelfth side LA3d opposing the tenth side LA3b.

The third side LA1c, the sixth side LA2b, the eighth side LA2d, the tenth side LA3b, and the twelfth side LA3d may extend in the first direction DR1. The second side LA1b, the fourth side LA1d, the seventh side LA2c, the ninth side LA3a, and the eleventh side LA3c may extend in the second direction DR2. The first side LA1a and the fifth side LA2a may extend in a fourth direction DR4.

The fourth direction DR4 may be a different direction from the first to third directions DR1, DR2, and DR3. For example, the fourth direction DR4 may extend in a diagonal direction different from the first direction DR1 and the second direction DR2, on the same plane as the first direction DR1 and the second direction DR2. The fourth direction DR4 may be perpendicular to the third direction DR3. For example, the fourth direction DR4 may extend diagonally on the same plane as, but at a different angle from, the first direction DR1 and the second direction DR2.

The display device 10 according to the present embodiment may include the second portion LA1-2 of the first emission area LA1 and the fourth portion LA2-2 of the second emission area LA2, so that edge discoloration may be minimized. Edge discoloration refers to a phenomenon in which a color other than white is displayed at the boundary when a black object is displayed on a white background or a white object is displayed on a black background.

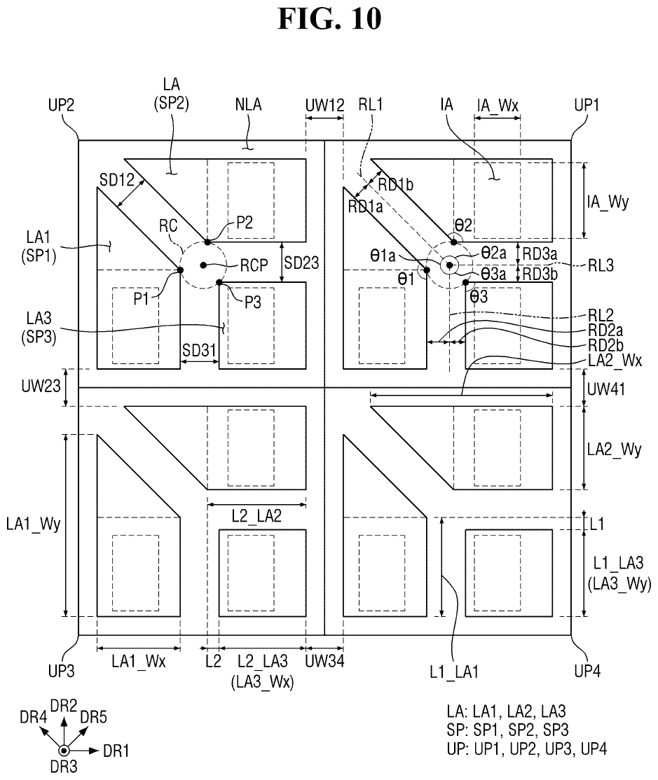

Specifically, the first side LA1a of the first emission area LA1 and the fifth side LA2a of the second emission area LA2 may extend in the fourth direction DR4, so that a deviation in the distribution of the upper, lower, left, and right emission areas LA may be reduced within one unit pixel. In addition, as illustrated in FIG. 10, which will be described later, the deviation in the distribution of the upper, lower, left, and right emission areas LA may be reduced in the relationship between the adjacent unit pixels UP. Accordingly, edge discoloration may be minimized.

The non-emission area NLA may be positioned around the emission area LA. The non-emission area NLA may surround the emission area LA. For example, the non-emission area NLA may be positioned not only around the emission area LA, but also between the first emission area LA1 and the second emission area LA2, between the second emission area LA2 and the third emission area LA3, and between the third emission area LA3 and the first emission area LA1.

The non-emission area NLA positioned at the peripheral portion of the emission area LA may surround the first to third emission areas LA1, LA2, and LA3. The non-emission area NLA positioned between the first emission area LA1 and the second emission area LA2 may extend in the fourth direction DR4. The non-emission area NLA positioned between the second emission area LA2 and the third emission area LA3 may extend in the first direction DR1. The non-emission area NLA positioned between the third emission area LA3 and the first emission area LA1 may extend in the second direction DR2.

The shapes of the first to third emission areas LA1, LA2, and LA3, the shape of the non-emission area NLA, and their disposition relationships will be further described later with reference to FIG. 10 or the like.

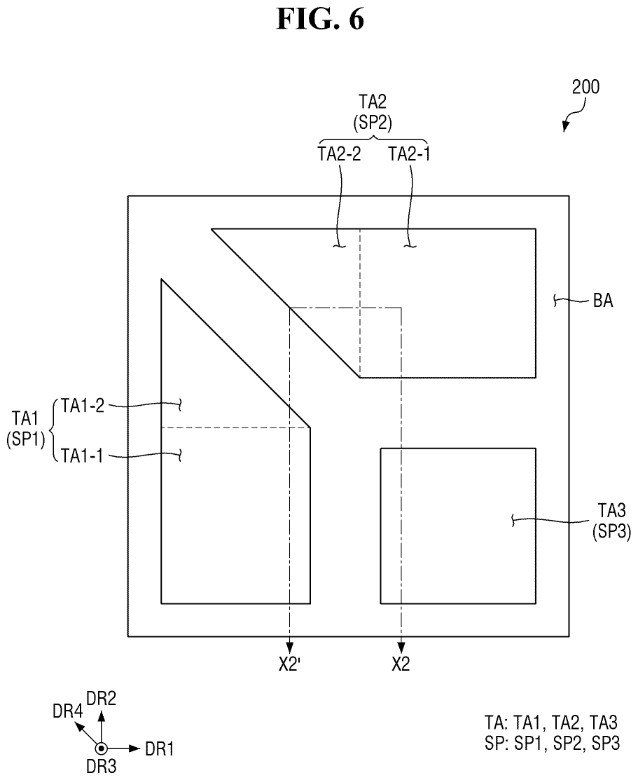

FIG. 6 is a plan view schematically illustrating light exit areas of a color conversion substrate according to an embodiment.

Referring to FIG. 6 in addition to FIG. 5, the color conversion substrate 200 may include a plurality of light exit areas TA and a light blocking area BA.

The plurality of light exit areas TA may be areas in which a color filter layer CFL (see FIG. 7) is exposed by the opening of a light blocking member BML (see FIG. 7), and the light blocking area BA may be an area in which the light blocking member BML (see FIG. 7) is positioned. For example, the plurality of light exit areas TA may be areas in which light generated by the display substrate 100 is provided to the outside, and the light blocking area BA may be an area in which light generated by the display substrate 100 is not provided to the outside. The boundary between the light exit area TA and the light blocking area BA may be defined by the opening of the light blocking member BML (see FIG. 7) and an outer wall surrounding the opening.

In an embodiment, the shape of the light exit area TA of the color conversion substrate 200 is the same as the shape of the emission area LA of the display substrate 100. The shape of the light blocking area BA of the color conversion substrate 200 may be the same as the shape of the non-emission area NLA of the display substrate 100. Light generated in the emission area LA of the display substrate 100 may pass through the light exit area TA of the color conversion substrate 200 and be provided to the outside of the display device 10.

Since the shape of the light exit area TA of the color conversion substrate 200 is the same as the shape of the emission area LA of the display substrate 100, and the shape of the light blocking area BA of the color conversion substrate 200 is the same as the shape of the non-emission area NLA of the display substrate 100, a detailed description thereof will be omitted. The description of the emission area LA described above may be equally applied to the light exit area TA within the same scope of technical spirit, and the description of the non-emission area NLA described above may be applied equally to the light blocking area BA within the same scope of technical spirit. The descriptions of the emission area LA and the non-emission area NLA, which will be described later, may also be applied equally to the light exit area TA and the light blocking area BA, respectively.

In FIG. 6, although the size (or area) of the light exit area TA of the color conversion substrate 200 is illustrated to be the same as the size (or area) of the emission area LA of the display substrate 100, and the size (or area) of the light blocking area BA of the color conversion substrate 200 is illustrated to be the same as the size (or area) of the non-emission area NLA of the display substrate 100, the present disclosure is not limited thereto. For example, the size (or area) of the light exit area TA of the color conversion substrate 200 may be smaller or larger than the size (or area) of the emission area LA of the display substrate 100, and the size (or area) of the light blocking area BA of the color conversion substrate 200 may be smaller or larger than the size (or area) of the non-emission area NLA of the display substrate 100.

FIG. 7 is a cross-sectional view of the display device according to an embodiment taken along line X2-X2′ of FIGS. 5 and 6.

Referring to FIG. 7 in addition to FIGS. 5 and 6, the display device 10 may include the display substrate 100, the color conversion substrate 200 facing the display substrate 100, and the filler 300 for bonding them.

In an embodiment, the display substrate 100 includes a first substrate 110, a circuit layer CCL, a light emitting element layer EML, and an encapsulation structure 170.

The first substrate 110 may include or be a transparent material. For example, the first substrate 110 may include a transparent insulating material such as glass, quartz, or the like. The first substrate 110 may be a rigid substrate. However, the first substrate 110 is not limited thereto, and may include plastic such as polyimide or the like, and may have a flexible property such that it can be twisted, bent, folded, or rolled.

The circuit layer CCL (for example, a thin film transistor layer) may be disposed on the first substrate 110. The circuit layer CCL may be a layer in which a circuit for driving a light emitting element is disposed. The circuit layer CCL may have various shapes and include various structures depending on the design method.

The light emitting element layer EML may be disposed on the circuit layer CCL. In an embodiment, the light emitting element layer EML includes a pixel electrode PXE, the pixel defining film PDL, the light emitting layer LEL, and a common electrode CME.

The pixel electrode PXE may be a first electrode (e.g., an anode electrode) of a light emitting diode. The pixel electrode PXE may have a stacked structure formed by stacking a material layer having a high work function and a reflective layer. Examples of the material layer include a layer formed of indium tin oxide (ITO), indium zinc oxide (IZO), zinc oxide (ZnO) or indium oxide (In₂O₃). Examples of the reflective layer include layer formed of a reflective material such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or a mixture thereof. The material layer having a high work function may be disposed above the reflective layer and disposed closer to the light emitting layer LEL. The pixel electrode PXE may have a multilayer structure such as ITO/Mg, ITO/MgF, ITO/Ag and ITO/Ag/ITO, but is not limited thereto.

The pixel electrode PXE may include a first pixel electrode PXR, a second pixel electrode PXG, and a third pixel electrode PXB. The first pixel electrode PXR may be disposed to overlap the first emission area LA1 and the first light exit area TA1. The second pixel electrode PXG may be disposed to overlap the second emission area LA2 and the second light exit area TA2. The third pixel electrode PXB may be disposed to overlap the third emission area LA3 and the third light exit area TA3.

The pixel defining film PDL may be disposed along the boundary of the pixel SP on one surface of the first substrate 110. The pixel defining film PDL may be disposed on the pixel electrode PXE and may include an opening to expose the pixel electrode PXE. The emission area LA and the non-emission area NLA may be distinguished by the pixel defining film PDL and the opening thereof.

The pixel defining film PDL may include an organic insulating material such as acrylic resin, epoxy resin, phenolic resin, polyamide resin, polyimide resin, unsaturated polyester resin, polyphenylene resin, polyphenylenesulfide resin or benzocyclobutene (BCB). The pixel defining film PDL may include an inorganic material.

The light emitting layer LEL may be disposed on the pixel electrode PXE exposed by the pixel defining film PDL. The light emitting layer LEL may be in contact with not only the pixel electrode PXE, but also the side surface and the top surface of the pixel defining film PDL. The light emitting layer LEL may be connected across the emission area LA and the pixel SP. The light emitting layer LEL may be disposed across the emission area LA and the pixel SP. Accordingly, the wavelength of light emitted from the light emitting layer LEL may be the same for each of the emission areas LA. For example, the light emitting layer LEL of each of the emission areas LA may emit blue light or ultraviolet rays, and the color conversion substrate 200 which will be described later may include a wavelength conversion layer WCL, thereby displaying a color for each pixel SP.

In an embodiment, the light emitting layers LEL are spaced apart from each other for each of the emission areas LA distinguished by the pixel defining film PDL. In this case, the wavelength of light emitted from each light emitting layer LEL may be the same for each of the emission areas LA.

In an embodiment in which the display device 10 is an organic light emitting display, the light emitting layer LEL includes an organic layer containing an organic material. The organic layer may have an organic light emitting layer, and in some cases, may further have at least one of a hole injection layer, a hole transport layer, an electron transport layer, or an electron injection layer as an auxiliary layer for light emission. In an embodiment, when the display device 10 is a micro LED display, a nano LED display or the like, the light emitting layer LEL may include an inorganic material such as an inorganic semiconductor.

In an embodiment, the light emitting layer LEL has a tandem structure in which a plurality of organic light emitting layers are superposed in the thickness direction and a charge generation layer is disposed between the organic light emitting layers. The respective organic light emitting layers superposed may emit light of the same wavelength, or may emit light of different wavelengths. At least some of the light emitting layers LEL of each pixel SP may be separated from or connected to the same layer of a neighboring pixel SP by the pixel defining film PDL.

The common electrode CME may be arranged on the light emitting layer LEL. The common electrode CME may be connected across the emission area LA and the pixel SP. The common electrode CME may be a full surface electrode disposed across the emission area LA and the pixel SP. The common electrode CME may be a second electrode (e.g., a cathode electrode) of a light emitting diode. The common electrode CME may include a material layer having a low work function, such as Li, Ca, LiF/Ca, LiF/Al, Al, Mg, Ag, Pt, Pd, Ni, Au Nd, Ir, Cr, BaF, Ba or a compound or mixture thereof (e.g., a mixture of Ag and Mg). The common electrode CME may further include a transparent metal oxide layer disposed on the material layer having a low work function.

The pixel electrode PXE, the light emitting layer LEL, and the common electrode CME may constitute a light emitting element (e.g., an OLED). Light emitted from the light emitting layer LEL may be emitted upward through the common electrode CME.

The encapsulation structure 170 may be disposed on the common electrode CME. The encapsulation structure 170 may include at least a thin film encapsulation layer. For example, the encapsulation structure 170 may include a first encapsulation inorganic film 171, an encapsulation organic film 172, and a second encapsulation inorganic film 173.

The first encapsulation inorganic film 171 may be disposed on the light emitting element layer EML. The first encapsulation inorganic film 171 may include silicon nitride (SiNₓ), silicon oxide (SiOₓ), silicon oxynitride (SiOₓN_{y}), or the like.

The encapsulation organic film 172 may be disposed on the first encapsulation inorganic film 171. The encapsulation organic film 172 may include an organic insulating material selected from the group consisting of acrylic resin, epoxy resin, phenolic resin, polyamide resin, polyimide resin, unsaturated polyester resin, polyphenylene ether resin, polyphenylenesulfide resin and benzocyclobutene (BCB).

The second encapsulation inorganic film 173 may be disposed on the encapsulation organic film 172. In an embodiment, the second encapsulation inorganic film 173 includes the same material as the first encapsulation inorganic film 171 described above. For example, the second encapsulation inorganic film 173 may include silicon nitride (SiNₓ), silicon oxide (SiOₓ), silicon oxynitride (SiOₓN_{y}), or the like.

In some embodiments, some layers of the encapsulation structure 170 or the entire encapsulation structure 170 may be omitted. When the encapsulation structure 170 is omitted, the filler 300, the sealing portion 400, and the color conversion substrate 200 may be directly disposed on the light emitting element layer EML, and the filler 300, the sealing portion 400, and the color conversion substrate 200 may directly perform an encapsulation function.

The color conversion substrate 200 may be disposed to face the display substrate 100 on the encapsulation structure 170. In an embodiment, the color conversion substrate 200 includes a second substrate 210, a light blocking member BML, a color filter layer CFL, a first capping layer 220, a partition wall PTL, a wavelength conversion layer WCL, a light transmitting layer TPL, and a second capping layer 230.

The second substrate 210 may include a transparent material. The second substrate 210 may include a transparent insulating material such as glass, quartz, or the like. The second substrate 210 may be a rigid substrate. However, the second substrate 210 is not limited thereto. The second substrate 210 may include plastic such as polyimide or the like, and may have a flexible property such that it can be twisted, bent, folded, or rolled.

The second substrate 210 may be made of the same material as the first substrate 110, but may have a different thickness or transmittance. For example, the second substrate 210 may have a higher transmittance than the first substrate 110. The second substrate 210 may be thicker or thinner than the first substrate 110.

The light blocking member BML may be disposed along the boundary of the pixel SP on one surface of the second substrate 210 that faces the first substrate 110. The light blocking member BML may overlap the non-emission area NLA of the display substrate 100 and may be positioned in the light blocking area BA. The light blocking member BML may include an opening exposing one surface of the second substrate 210 that overlaps the emission area LA and the light exit area TA. The light blocking member BML may be formed in a grid shape in a plan view.

The light blocking member BML may include an organic material. The light blocking member BML may reduce color distortion due to external light reflection by absorbing the external light. Further, the light blocking member BML may serve to prevent light which is emitted from the light emitting layer LEL from entering the adjacent pixels SP.

In an embodiment, the light blocking member BML is configured to absorb all visible wavelengths. The light blocking member BML may include a light absorbing material. For example, the light blocking member BML may be formed of a material used as a black matrix of the display device 10.

In an embodiment, the light blocking member BML is configured to absorb light of a specific wavelength among visible wavelengths and transmit light of other wavelengths. For example, the light blocking member BML may include the same material as the color filter layer CFL. Specifically, the light blocking member BML may be made of the same material as a blue color filter layer. In an embodiment, the light blocking member BML is integrally formed with the blue color filter layer. Alternatively, the light blocking member BML may be omitted.

The color filter layer CFL may be disposed on one surface of the second substrate 210 on which the light blocking member BML is disposed. The color filter layer CFL may be provided on the surface of the second substrate 210 which is exposed through the openings of the light blocking member BML. Further, each color filter layer CFL may be partially disposed on the adjacent light blocking member BML.

The color filter layer CFL may include a first color filter layer CFL1 disposed in the first sub-pixel SP1, a second color filter layer CFL2 disposed in the second pixel SP2, and a third color filter layer CFL3 disposed in the third pixel SP3. Each color filter layer CFL may include a colorant such as a dye or a pigment that absorbs wavelengths other than the corresponding color wavelength. The first color filter layer CFL1 may be a red color filter layer, the second color filter layer CFL2 may be a green color filter layer, and the third color filter layer CFL3 may be a blue color filter layer.

Although FIG. 7 illustrates a case where the neighboring color filter layers CFL are disposed to be spaced apart from each other on the light blocking member BML, the neighboring color filter layers CFL may partially overlap each other on the light blocking member BML.

The first capping layer 220 may be disposed on the color filter layer CFL. The first capping layer 220 may prevent impurities such as moisture or air from permeating from the outside and damaging or contaminating the color filter layer CFL. Further, the first capping layer 220 may prevent the colorant of the color filter layer CFL from being diffused into other members.

The first capping layer 220 may be in direct contact with one surface (bottom surface in FIG. 7) of the color filter layer CFL. The first capping layer 220 may be made of an inorganic material. For example, the first capping layer 220 may include silicon nitride, aluminum nitride, zirconium nitride, titanium nitride, hafnium nitride, tantalum nitride, silicon oxide, aluminum oxide, titanium oxide, tin oxide, silicon oxynitride, or the like.

The partition wall PTL may be disposed on the first capping layer 220. The partition wall PTL may be positioned in the non-emission area NLA. In an embodiment, the partition wall PTL is disposed to overlap the light blocking member BML. The partition wall PTL may include openings exposing the color filter layer CFL. The partition wall PTL may include a photosensitive organic material, but the present disclosure is not limited thereto. The partition wall PTL may further include a light blocking material.

The wavelength conversion layer WCL and/or the light transmitting layer TPL may be disposed in the space exposed by the opening of the partition wall PTL. The wavelength conversion layer WCL and the light transmitting layer TPL may be formed by an inkjet process using the partition wall PTL as a bank, but the present disclosure is not limited thereto.

In an embodiment in which the light emitting layer LEL of each pixel SP emits light in a third color, the wavelength conversion layer WCL may include a first wavelength conversion pattern WCL1 disposed in the first sub-pixel SP1 and a second wavelength conversion pattern WCL2 disposed in the second sub-pixel SP2. The light transmitting layer TPL may be disposed in the third sub-pixel SP3.

The first wavelength conversion pattern WCL1 may include a first base resin BRS1 and a first wavelength conversion material WCP1 provided in the first base resin BRS1. The second wavelength conversion pattern WCL2 may include a second base resin BRS2 and a second wavelength conversion material WCP2 provided in the second base resin BRS2. The light transmitting layer TPL may include a third base resin BRS3 and a scatterer SCP provided in the third base resin BRS3.

The first to third base resins BRS1, BRS2, and BRS3 may include a light transmitting organic material. For example, the first to third base resins BRS1, BRS2, and BRS3 may include an epoxy resin, an acrylic resin, a cardo resin, an imide resin, or the like. The first to third base resins BRS1, BRS2 and BRS3 may be formed of the same material, but the present disclosure is not limited thereto.

The scatterer SCP may be a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like.

The first wavelength conversion material WCP1 may convert the third color into the first color, and the second wavelength conversion material WCP2 may convert the third color into the second color. The first wavelength conversion material WCP1 and the second wavelength conversion material WCP2 may be quantum dots, quantum bars, phosphors or the like. Examples of the quantum dot may include group IV nanocrystal, group II-VI compound nanocrystal, group III-V compound nanocrystal, group IV-VI nanocrystal, and a combination thereof. The first wavelength conversion pattern WCL1 and the second wavelength conversion pattern WCL2 may further include a scatterer SCP for increasing wavelength conversion efficiency.

The light transmitting layer TPL disposed in the third sub-pixel SP3 may transmit light of a third color emitted from the light emitting layer LEL while maintaining the wavelength thereof. The scatterer SCP of the light transmitting layer TPL may serve to control an emission path of the light emitted through the light transmitting layer TPL. In an embodiment, the light transmitting layer TPL does not include any wavelength conversion material. For example, in this embodiment, the light transmitting layer TPL does not include materials like WCP1 or WCP2.

The second capping layer 230 may be disposed on the wavelength conversion layer WCL, the light transmitting layer TPL, and the partition wall PTL. The second capping layer 230 may be formed of an inorganic material. The second capping layer 230 may include a material selected from the above-mentioned materials of the first capping layer 220. The first capping layer 220 and the second capping layer 230 may be formed of the same material, but the present disclosure is not limited thereto.

The filler 300 may be disposed between the display substrate 100 and the color conversion substrate 200. The filler 300 may fill a space between the display substrate 100 and the color conversion substrate 200, and may serve to bond them to each other. The filler 300 may be disposed between the encapsulation structure 170 of the display substrate 100 and the second capping layer 230 of the color conversion substrate 200. The filler 300 may be formed of a Si-based organic material, an epoxy-based organic material, or the like, but is not limited thereto.

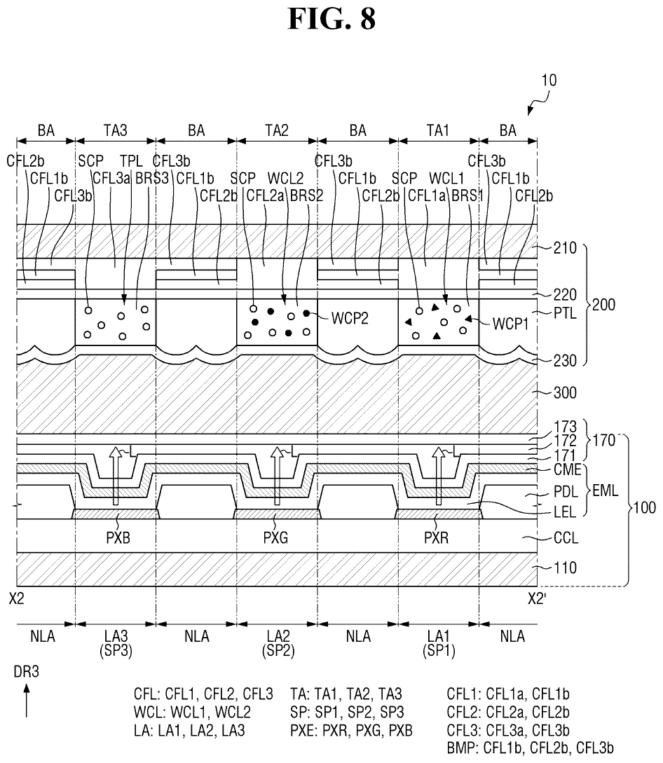

FIG. 8 is a cross-sectional view of the display device according to an embodiment.

Referring to FIG. 8, the display device 10 according to the present embodiment is different from the display device 10 of FIG. 7 in that the color conversion substrate 200 does not include the light blocking member BML.

More specifically, the display device 10 according to the present embodiment does not include the light blocking member BML. The color filter layer CFL of the display device 10 according to the present embodiment may include a filtering pattern area and a light blocking pattern portion BMP. The light blocking pattern portion BMP may surround the filtering pattern area. The filtering pattern area of the color filter layer CFL may define the light exit area TA, and the light blocking pattern portion BMP may define the light blocking area BA.

The color filter layer CFL may include the first color filter layer CFL1, the second color filter layer CFL2, and the third color filter layer CFL3.

The first color filter layer CFL1 may include a first filtering pattern area CFL1a and a first light blocking pattern area CFL1b surrounding the first filtering pattern area CFL1a. The second color filter layer CFL2 may include a second filtering pattern area CFL2a and a second light blocking pattern area CFL2b surrounding the second filtering pattern area CFL2a. The third color filter layer CFL3 may include a third filtering pattern area CFL3a and a third light blocking pattern area CFL3b surrounding the third filtering pattern area CFL3a.

The first filtering pattern area CFL1a may overlap the first light exit area TA1. The second filtering pattern area CFL2a may overlap the second light exit area TA2. The third filtering pattern area CFL3a may overlap the third light exit area TA3.

The first light blocking pattern area CFL1b may surround the first filtering pattern area CFL1a. The second light blocking pattern area CFL2b may surround the second filtering pattern area CFL2a. The third light blocking pattern area CFL3b may surround the third filtering pattern area CFL3a.

In an embodiment, the first light blocking pattern area CFL1b does not overlap the second light exit area TA2 and the third light exit area TA3. In an embodiment, the second light blocking pattern area CFL2b does not overlap the first light exit area TA1 and the third light exit area TA3. In an embodiment, the third light blocking pattern area CFL3b does not overlap the first light exit area TA1 and the second light exit area TA2.

The filtering pattern area of the color filter layer CFL may include the first filtering pattern area CFL1a of the first color filter layer CFL1, the second filtering pattern area CFL2a of the second color filter layer CFL2, and the third filtering pattern area CFL3a of the third color filter layer CFL3.

The light blocking pattern portion BMP of the color filter layer CFL may include the first light blocking pattern area CFL1b of the first color filter layer CFL1, the second light blocking pattern area CFL2b of the second color filter layer CFL2, and the third light blocking pattern area CFL3b of the third color filter layer CFL3.

The first filtering pattern area CFL1a of the first color filter layer CFL1 may function as a blocking filter that blocks light of the second color and light of the third color. For example, the first filtering pattern area CFL1a of the first color filter layer CFL1 may block or absorb green light and blue light, and may selectively transmit red light.

The second filtering pattern area CFL2a of the second color filter layer CFL2 may function as a blocking filter that blocks light of the first color and light of the third color. For example, the second filtering pattern area CFL2a of the second color filter layer CFL2 may block or absorb red light and blue light, and may selectively transmit green light.

The third filtering pattern area CFL3a of the third color filter layer CFL3 may function as a blocking filter that blocks light of the first color and light of the second color. For example, the third filtering pattern area CFL3a of the third color filter layer CFL3 may block or absorb red light and green light, and may selectively transmit blue light.

The light blocking pattern portion BMP may be a structure in which a third light blocking pattern area CFL3b, a first light blocking pattern area CFL1b, and a second light blocking pattern area CFL2b are sequentially stacked in a direction opposite to the third direction DR3. The light blocking pattern portion BMP may absorb all of light of the first color, light of the second color, and light of the third color. For example, the light blocking pattern portion BMP may absorb all of red light, green light, and blue light.

The display device 10 according to the present embodiment forms the light blocking pattern portion BMP by overlapping at least a part of the first to third color filter layers CFL1, CFL2, and CFL3, so that an additional process for forming the separate light blocking member BML is not performed. Accordingly, process efficiency may be increased. Additionally, the thickness of the display device 10 may be reduced.

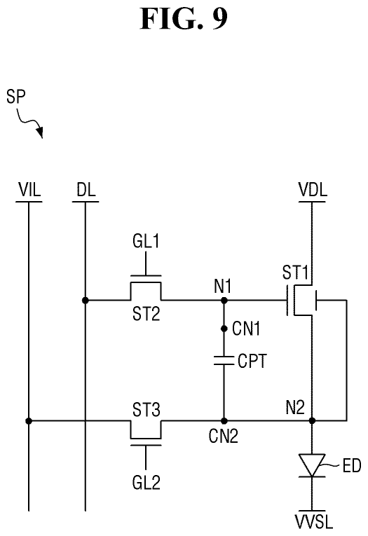

FIG. 9 is a circuit diagram illustrating a pixel circuit and a wiring connected to the pixel circuit of the display device according to an embodiment.

Referring to FIG. 9, each of the pixels SP may be connected to the first voltage line VDL, the data line DL, the initialization voltage line VIL, the first gate line GL1, the second gate line GL2, and the vertical voltage line VVSL. The elements depicted in FIG. 9 correspond to one sub-pixel of a given pixel SP such as SP1.

Each sub-pixel may include a pixel circuit and a light emitting element ED. The pixel circuit of each sub-pixel may include first to third transistors ST1, ST2, and ST3 and a capacitor CPT.

The first transistor ST1 may include an upper gate electrode, a lower gate electrode, a drain electrode, and a source electrode. The upper gate electrode of the first transistor ST1 may be connected to a first node N1, the lower gate electrode thereof may be connected to a second node N2, the drain electrode thereof may be connected to the first voltage line VDL, and the source electrode thereof may be connected to the second node N2. The first transistor ST1 may control a drain-source current (or a driving current) based on the data voltage applied to the upper gate electrode and the lower gate electrode. The first transistor ST1 may be a driving transistor for driving the light emitting element ED.

The light emitting element ED may emit light by receiving a driving current. The light emission amount or the luminance of the light emitting element ED may be proportional to the magnitude of the driving current. The light emitting element ED may be an organic light emitting diode (OLED) having an organic light emitting layer, a quantum dot light emitting diode (LED) including a quantum dot light emitting layer, a micro LED, or an inorganic LED having an inorganic semiconductor.

The first electrode of the light emitting element ED may be connected to the second node N2, and the second electrode of the light emitting element ED may be connected to the vertical voltage line VVSL. The first electrode of the light emitting element ED may be connected to the source electrode of the first transistor ST1, the drain electrode of the third transistor ST3, and a second capacitor node CN2 of the capacitor CPT, through the second node N2.

The second transistor ST2 may be turned on by a first gate signal applied to the first gate line GL1 to electrically connect the data line DL to the first node N1 which is the upper gate electrode of the first transistor ST1. For example, when FIG. 9 depicts the first sub-pixel SP1, the data line may be DL1. The second transistor ST2 may be turned on based on the first gate signal to supply the data voltage to the first node N1. The gate electrode of the second transistor ST2 may be connected to the first gate line GL1, the drain electrode thereof may be connected to the data line DL, and the source electrode thereof may be connected to the first node N1. The source electrode of the second transistor ST2 may be connected to the upper gate electrode of the first transistor ST1 and a first capacitor node CN1 of the capacitor CPT through the first node N1. The second transistor ST2 may be a switching transistor for controlling the current flowing through the first transistor ST1 and the light emitting element ED.

The third transistor ST3 may be turned on by a second gate signal applied to the second gate line GL2 to electrically connect the initialization voltage line VIL to the second node N2 which is the source electrode of the first transistor ST1. The third transistor ST3 may be turned on according to the second gate signal to supply the initialization voltage to the second node N2. The third transistor ST3 may be turned on according to the second gate signal to supply the sensing signal to the initialization voltage line VIL. The gate electrode of the third transistor ST3 may be connected to the second gate line GL2, the drain electrode thereof may be connected to the second node N2, and the source electrode thereof may be connected to the initialization voltage line VIL. The drain electrode of the third transistor ST3 may be connected to the source electrode of the first transistor ST1 and the first electrode of the light emitting element ED through the second node N2, and may be connected to the second capacitor node CN2 of the capacitor CPT. The third transistor ST3 may be a switching transistor for controlling the current flowing through the first transistor ST1 and the light emitting element ED.

The capacitor CPT may include a first capacitor, a second capacitor, and a third capacitor. The first capacitor, the second capacitor, and the third capacitor may be connected in parallel to each other through the first capacitor node CN1 and the second capacitor node CN2. Accordingly, the total capacitance of the capacitor CPT may be equal to the sum of the respective capacitances of the first capacitor, the second capacitor, and the third capacitor.

One electrode of each of the first capacitor, the second capacitor, and the third capacitor may be connected to the first node N1 through the first capacitor node CN1. The other electrode of each of the first capacitor, the second capacitor, and the third capacitor may be connected to the second node N2 through the second capacitor node CN2.

FIG. 10 is a plan view showing disposition of emission areas included in unit pixels according to an embodiment.

Referring to FIG. 10 in addition to FIGS. 5 and 6, the display substrate 100 may include the plurality of unit pixels UP. As shown in FIG. 10, the plurality of unit pixels UP may include a first unit pixel UP1, a second unit pixel UP2, a third unit pixel UP3, and a fourth unit pixel UP4. In FIG. 10, only four unit pixels UP are illustrated, but the number of the unit pixels UP is not limited thereto.

The first unit pixel UP1 may be disposed on one side of the second unit pixel UP2 in the first direction DR1, and may be disposed on one side of the fourth unit pixel UP4 in the second direction DR2. The second unit pixel UP2 may be disposed on the other side of the first unit pixel UP1 in the first direction DR1 and may be disposed on one side of the third unit pixel UP3 in the second direction DR2. The third unit pixel UP3 may be disposed on the other side of the second unit pixel UP2 in the second direction DR2 and may be disposed on the other side of the fourth unit pixel UP4 in the first direction DR1. The fourth unit pixel UP4 may be disposed on the other side of the first unit pixel UP1 in the second direction DR2 and may be disposed on one side of the third unit pixel UP3 in the first direction DR1.

In an embodiment, the distance between the adjacent unit pixels UP are the same. In an embodiment, the width of the non-emission area NLA (or the light blocking area BA) positioned between the adjacent unit pixels UP is constant. For example, a width UW12 in the first direction DR1 of the non-emission area NLA (or the light blocking area BA) positioned between the first unit pixel UP1 and the second unit pixel UP2, a width UW23 in the second direction DR2 of the non-emission area NLA (or the light blocking area BA) positioned between the second unit pixel UP2 and the third unit pixel UP3, a width UW34 in the first direction DR1 of the non-emission area NLA (or the light blocking area BA) positioned between the third unit pixel UP3 and the fourth unit pixel UP4, and a width UW41 in the second direction DR2 of the non-emission area NLA (or the light blocking area BA) positioned between the fourth unit pixel UP4 and the first unit pixel UP1 may be the same.

The pixels SP of the first to fourth unit pixels UP1, UP2, UP3, and UP4 may have the same shape and disposition structure. For example, each of the first to fourth unit pixels UP1, UP2, UP3, and UP4 may include the first sub-pixel SP1, the second sub-pixel SP2, and the third sub-pixel SP3.

The emission areas LA of the first to fourth unit pixels UP1, UP2, UP3, and UP4 may have the same shape and disposition structure. For example, each of the first to fourth unit pixels UP1, UP2, UP3, and UP4 may include the first emission area LA1, the second emission area LA2, and the third emission area LA3.

However, the present disclosure is not limited thereto, and the pixels SP of the first to fourth unit pixels UP1, UP2, UP3, and UP4 and the emission areas LA of the first to fourth unit pixels UP1, UP2, UP3, and UP4 may have different shapes and disposition structures.

Hereinafter, when the first to fourth unit pixels UP1, UP2, UP3, and UP4 are not specifically stated, it may be understood as a description corresponding to at least one of the first to fourth unit pixels UP1, UP2, UP3, and UP4.

In an embodiment, the distance between the adjacent sub-pixels within one unit pixel UP are the same. In an embodiment, the width of the non-emission area NLA (or the light blocking area BA) positioned between the adjacent sub-pixels within one unit pixel UP is constant. For example, a width SD12 of the non-emission area NLA (or the light blocking area BA) positioned between the first sub-pixel SP1 and the second sub-pixel SP2, a width SD23 in the second direction DR2 of the non-emission area NLA (or the light blocking area BA) positioned between the second sub-pixel SP2 and the third sub-pixel SP3, and a width SD31 in the first direction DR1 of the non-emission area NLA (or the light blocking area BA) positioned between the third sub-pixel SP3 and the first sub-pixel SP1 may be the same. The width SD12 of the non-emission area NLA (or the light blocking area BA) positioned between the first sub-pixel SP1 and the second sub-pixel SP2 may mean a separation distance between the first sub-pixel SP1 and the second sub-pixel SP2 in a fifth direction DR5.

The fifth direction DR5 may intersect the fourth direction DR4 on the same plane as the fourth direction DR4. The fifth direction DR5 may be a direction perpendicular to the fourth direction DR4 on the same plane as the fourth direction DR4.

In an embodiment, an angle θ1 formed by the first side LA1a and the second side LA1b of the first emission area LA1 is an obtuse angle. In an embodiment, an angle θ2 formed by the fifth side LA2a and the sixth side LA2b of the second emission area LA2 is an obtuse angle. In an embodiment, an angle θ3 formed by the ninth side LA3a and the tenth side LA3b of the third emission area LA3 is a right angle.

An angle formed by the extension direction of the non-emission area NLA (or the light blocking area BA) positioned between the first emission area LA1 and the second emission area LA2 and the extension direction of the non-emission area NLA (or the light blocking area BA) positioned between the third emission area LA3 and the first emission area LA1 may be an obtuse angle. An angle formed by the extension direction of the non-emission area NLA (or the light blocking area BA) positioned between the first emission area LA1 and the second emission area LA2 and the extension direction of the non-emission area NLA (or the light blocking area BA) positioned between the second emission area LA2 and the third emission area LA3 may be an obtuse angle. An angle formed by the extension direction of the non-emission area NLA (or the light blocking area BA) positioned between the third emission area LA3 and the first emission area LA1 and the extension direction of the non-emission area NLA (or the light blocking area BA) positioned between the second emission area LA2 and the third emission area LA3 may be a right angle.

The first to third emission areas LA1, LA2, and LA3 may include first to third vertices P1, P2, and P3 located at positions at which the first to third emission areas LA1, LA2, and LA3 face each other. For example, the first emission area LA1 may include the first vertex P1 positioned at a position facing the second emission area LA2 and the third emission area LA3, the second emission area LA2 may include the second vertex P2 positioned at a position facing the first emission area LA1 and the third emission area LA3, and the third emission area LA3 may include the third vertex P3 positioned at a position facing the first emission area LA1 and the second emission area LA2.

In some embodiments, the unit pixel UP may include a reference circle RC passing through the first to third vertices P1, P2, and P3. The reference circle RC is defined as a circle passing through all of the first to third vertices P1, P2, and P3, and may be a virtual circle.

The unit pixel UP may include a first reference line RL1 extending in the fourth direction DR4, a second reference line RL2 extending in the second direction DR2, and a third reference line RL3 extending in the first direction DR1, from a center RCP of the reference circle RC.

In an embodiment, the angle formed by an angle θ1a formed by the first reference line RL1 and the second reference line RL2 is an obtuse angle, the angle formed by an angle θ2a formed by the first reference line RL1 and the third reference line RL3 is an obtuse angle, and the angle formed by an angle θ3a formed by the second reference line RL2 and the third reference line RL3 is a right angle.

In an embodiment, the first emission area LA1 and the second emission area LA2 are spaced apart from one another by the same distance with respect to the first reference line RL1. For example, a distance RD1a in the fifth direction DR5 between the first emission area LA1 and the first reference line RL1 may be the same as a distance RD1b in the fifth direction DR5 between the second emission area LA2 and the first reference line RL1.

The first emission area LA1 and the third emission area LA3 may be spaced apart by different distances with respect to the second reference line RL2. For example, a distance RD2a in the first direction DR1 between the first emission area LA1 and the second reference line RL2 may be different from a distance RD2b in the first direction DR1 between the third emission area LA3 and the second reference line RL2. The distance RD2a in the first direction DR1 between the first emission area LA1 and the second reference line RL2 may be greater than the distance RD2b in the first direction DR1 between the third emission area LA3 and the second reference line RL2.

The second emission area LA2 and the third emission area LA3 may be spaced apart by different distances with respect to the third reference line RL3. For example, a distance RD3a in the second direction DR2 between the second emission area LA2 and the third reference line RL3 may be different from a distance RD3b in the second direction DR2 between the third emission area LA3 and the third reference line RL3. The distance RD3a in the second direction DR2 between the second emission area LA2 and the third reference line RL3 may be greater than the distance RD3b in the second direction DR2 between the third emission area LA3 and the third reference line RL3.

With respect to the first reference line RL1, a width of one area and a width of the other area of the non-emission area NLA positioned between the first emission area LA1 and the second emission area LA2 may be the same. For example, a width in the fifth direction DR5 of the non-emission area NLA positioned between the first reference line RL1 and the first emission area LA1 may be equal to a width in the fifth direction DR5 of the non-emission area NLA positioned between the first reference line RL1 and the second emission area LA2.

With respect to the second reference line RL2, a width of one area and a width of the other area of the non-emission area NLA positioned between the first emission area LA1 and the third emission area LA3 may be different from each other. For example, a width in the first direction DR1 of the non-emission area NLA positioned between the second reference line RL2 and the first emission area LA1 may be different from a width in the first direction DR1 of the non-emission area NLA positioned between the second reference line RL2 and the third emission area LA3. The width in the first direction DR1 of the non-emission area NLA positioned between the second reference line RL2 and the first emission area LA1 may be greater than the width in the first direction DR1 of the non-emission area NLA positioned between the second reference line RL2 and the third emission area LA3.

With respect to the third reference line RL3, a width of one area and a width of the other area of the non-emission area NLA positioned between the second emission area LA2 and the third emission area LA3 may be different from each other. For example, a width in the second direction DR2 of the non-emission area NLA positioned between the third reference line RL3 and the second emission area LA2 may be different from a width in the second direction DR2 of the non-emission area NLA positioned between the third reference line RL3 and the third emission area LA3. In an embodiment, a width in the second direction DR2 of the non-emission area NLA positioned between the third reference line RL3 and the second emission area LA2 is greater than a width in the second direction DR2 of the non-emission area NLA positioned between the third reference line RL3 and the third emission area LA3.

In an embodiment, a length L1_LA1 in the second direction DR2 of the first portion LA1-1 of the first emission area LA1 is longer than a length L1_LA3 in the second direction DR2 of the third emission area LA3. For example, a length in the second direction DR2 of the second side LA1b of the first emission area LA1 may be longer than a length in the second direction DR2 of the ninth side LA3a and a length in the second direction DR2 of the eleventh side LA3c of the third emission area LA3 by a first length difference L1. The first vertex P1 may be disposed closer to the center RCP of the reference circle RC in the second direction DR2 than the third vertex P3.

In an embodiment, a length L2_LA2 in the first direction DR1 of the third portion LA2-1 of the second emission area LA2 is longer than a length L2_LA3 in the first direction DR1 of the third emission area LA3. For example, a length in the first direction DR1 of the sixth side LA2b of the second emission area LA2 may be longer than a length in the first direction DR1 of the tenth side LA3b and a length in the first direction DR1 of the twelfth side LA3d of the third emission area LA3 by a second length difference L2. The second vertex P2 may be disposed closer to the center RCP of the reference circle RC in the first direction DR1 than the third vertex P3.

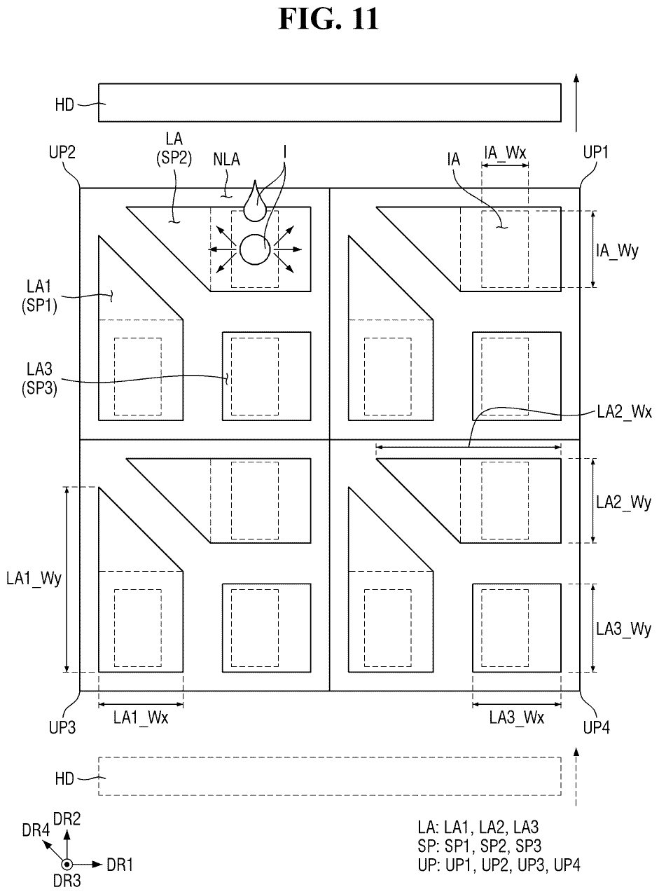

FIG. 11 is a plan view illustrating a process in which ink is ejected to an emission area to form a light emitting layer according to an embodiment.

Referring to FIG. 11 in addition to FIGS. 5, 6, and 10, the light emitting layer LEL (see FIG. 7) of the display device 10 may be formed by an inkjet process. The light emitting layer LEL (see FIG. 7) may include an ink I material. The ink I material may include materials remaining after the solvent of the ink I has volatilized. For example, the ink I material may include not only a solute component such as an organic light emitting material, but also a solvent remaining after volatilization, and other additives that allow the solvent and the solute to mix well.

The ink I may be ejected from an inkjet head HD. The inkjet head HD may move in one direction on the display substrate 100 and eject the ink I. The ejected ink I may land in the emission area LA.

For example, as illustrated in FIG. 11, the inkjet head HD may move in the second direction DR2 and eject the ink I. The ink I may land on an area within a certain range depending on the nozzle position of the inkjet head HD, the moving speed of the inkjet head HD, the ink I ejection speed, or the like. The area in which the ink I may land may be a landing area IA.

The landing area IA may be positioned in the first portion LA1-1 of the first emission area LA1, the third portion LA2-1 of the second emission area LA2, and the third emission area LA3. When the ink I lands on the first portion LA1-1 and the third portion LA2-1, the diffusivity of the ink I may allow the ink I to spread to and fill the second portion LA1-2 and the fourth portion LA2-2.

The landing area IA may have a shape extending in the moving direction of the inkjet head HD. The landing area IA may include a short side and a long side respectively extending in the first direction DR1 and the second direction DR2, which are the disposition directions of the unit pixel UP. For example, as illustrated in FIG. 11, when the landing area IA has a quadrilateral shape, a width IA_Wy in the second direction DR2, which is the moving direction of the inkjet head HD, may be longer than a width IA_Wx in the first direction DR1.

The width of the emission area LA may be influenced by the width of the landing area IA. The width of the emission area LA may be greater than or equal to the width of the landing area IA. For example, the width of each of the first to third emission areas LA1, LA2, and LA3 may be greater than or equal to the width of the landing area IA.

A width LA1_Wx in the first direction DR1 of the first emission area LA1, a width LA2_Wx in the first direction DR1 of the second emission area LA2, and a width LA3_Wx in the first direction DR1 of the third emission area LA3 may be greater than or equal to the width IA_Wx in the first direction DR1 of the landing area IA.

A width LA1_Wy in the second direction DR2 of the first emission area LA1, a width LA2_Wy in the second direction DR2 of the second emission area LA2, and a width LA3_Wy in the second direction DR2 of the third emission area LA3 may be greater than or equal to the width IA_Wy in second direction DR2 of the landing area IA.

Accordingly, it is possible to prevent a mis-landing phenomenon in which the ink I lands in an area other than the emission area LA, for example, the non-emission area NLA.

As the display device 10 has a high-resolution pixel structure, the width of the non-emission area NLA (or the light blocking area BA) may be reduced to secure the margin of the landing area IA of the ink I.

The display device 10 according to the present embodiment may increase the area division efficiency by including the second portion LA1-2 and the fourth portion LA2-2 extending in directions different from the first direction DR1 and the second direction DR2, which are the disposition directions of the unit pixel UP, or the non-emission area NLA disposed between the second portion LA1-2 and the fourth portion LA2-2, so that the reduction in line width of the non-emission area NLA or light blocking area BA may be minimized for securing the margin of the landing area IA.

Accordingly, the margin of the landing area IA may be secured while maintaining the line width of the non-emission area NLA or the light blocking area BA without reducing the line width. By maintaining the line width of the non-emission area NLA or the light blocking area BA, color mixing between pixels SP may be prevented. Additionally, since there is no need to achieve a fine line width even in a high-resolution pixel structure, the manufacturing process may be simplified.

Hereinafter, other embodiments of the display device according to an embodiment will be described. In the following embodiments, description of the same components as those of the above-described embodiment, which are denoted by like reference numerals, will be omitted or simplified, and differences will be mainly described.

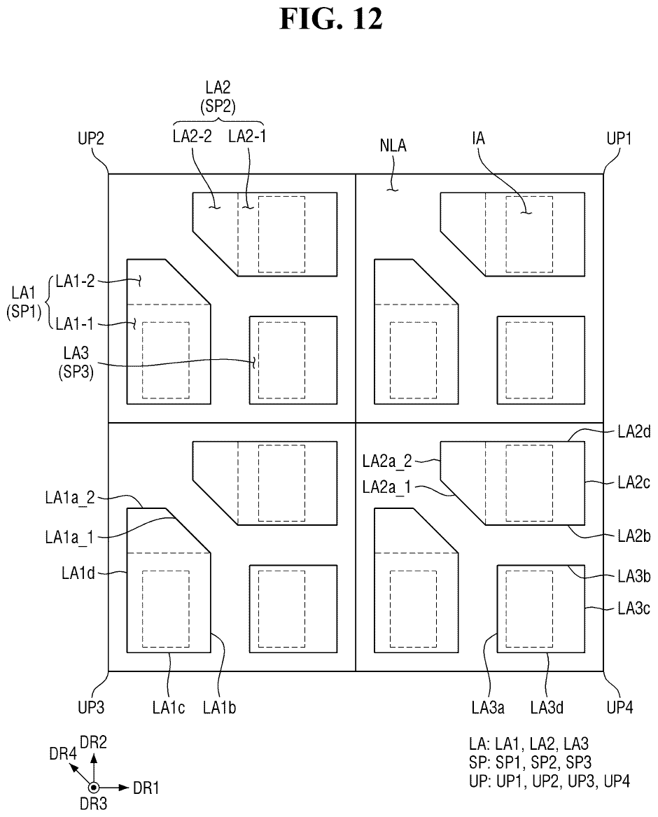

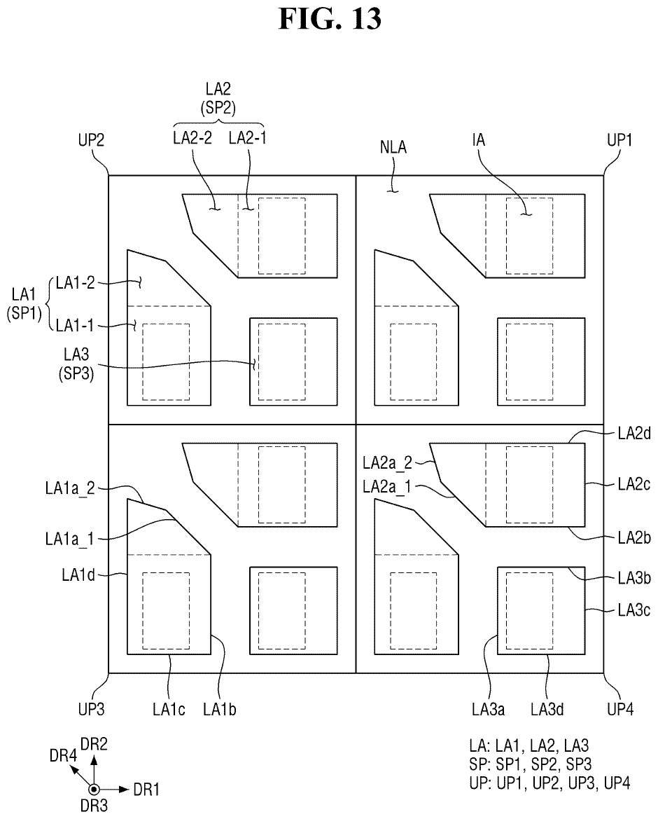

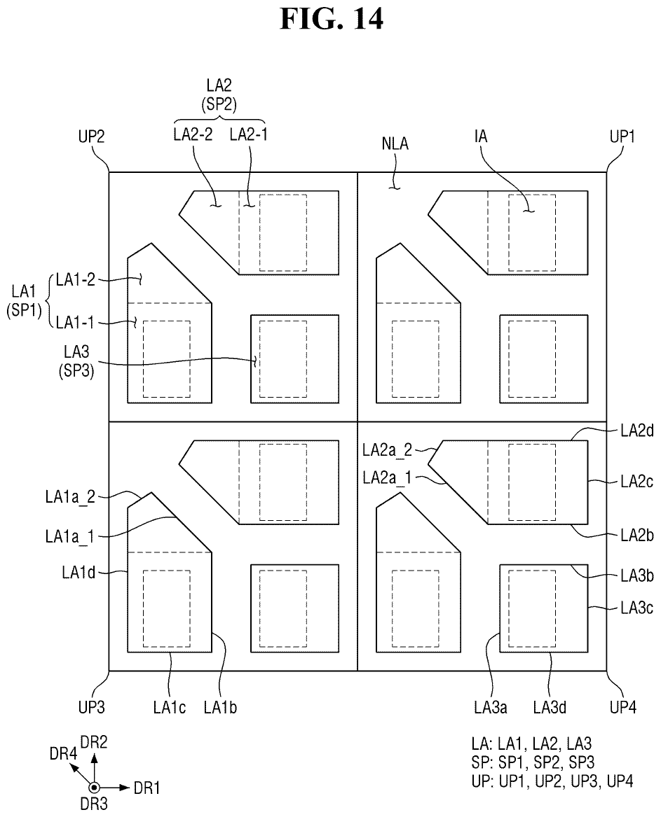

FIG. 12 is a plan view showing disposition of emission areas included in unit pixels according to an embodiment. FIG. 13 is a plan view showing disposition of emission areas included in unit pixels according to an embodiment. FIG. 14 is a plan view showing the disposition of emission areas included in unit pixels according to an embodiment.

Referring to FIGS. 12 to 14, the display device 10 according to the present embodiment is different from the display device 10 according to the embodiment described with reference to FIG. 10 that the shapes of the second portion LA1-2 and the fourth portion LA2-2 are different.

More specifically, the first to third emission areas LA1, LA2, and LA3 may have a polygonal shape. The first emission area LA1 and the second emission area LA2 may have a pentagonal shape, and the third emission area LA3 may have a rectangular (or square) shape. The second portion LA1-2 of the first emission area LA1 and the fourth portion LA2-2 of the second emission area LA2 may have a quadrilateral shape.

The first emission area LA1 may include a first side LA1a_1 facing the second emission area LA2, the second side LA1b facing the third emission area LA3, the third side LA1c connected to one side of the second side LA1b, the fourth side LA1d opposing the second side LA1b, and a first chamfered side LA1a_2 positioned between the first side LA1a_1 and the fourth side LA1d. For example, the upper left corner of the second portion LA1-2 of FIG. 5 could be beveled or cut away to create a flattened or truncated side to form the first chamfered side LA1a_2. A chamfered side may also be referred to as a beveled side, a truncated corner, a flattened edge or an angled corner.

The second emission area LA2 may include a fifth side LA2a_1 facing the first emission area LA1, the sixth side LA2b facing the third emission area LA3, the seventh side LA2c connected to one side of the sixth side LA2b, the eighth side LA2d opposing the sixth side LA2b, and a second chamfered side LA2a_2 positioned between the fifth side LA2a_1 and the eighth side LA2d. For example, the upper left corner of the second portion LA2-2 of FIG. 5 could be beveled or cut away to create a flattened or truncated side to form the second chamfered side LA2a_2.

In an embodiment, as illustrated in FIG. 12, the first chamfered side LA1a_2 extends in the first direction DR1. In an embodiment, as illustrated in FIGS. 13 and 14, the first chamfered side LA1a_2 extends in a direction different from the first to fourth directions DR4. The first chamfered side LA1a_2 may extend downward to the right as illustrated in FIG. 13 or may extend upward to the right as illustrated in FIG. 14.

As illustrated in FIGS. 12 to 14, the display device 10 according to the present embodiment may adjust the area ratio of the first to third emission areas LA1, LA2, and LA3 by adjusting the shapes of the second portion LA1-2 and the fourth portion LA2-2. Accordingly, the color tone of the color displayed by the unit pixel UP may be adjusted.

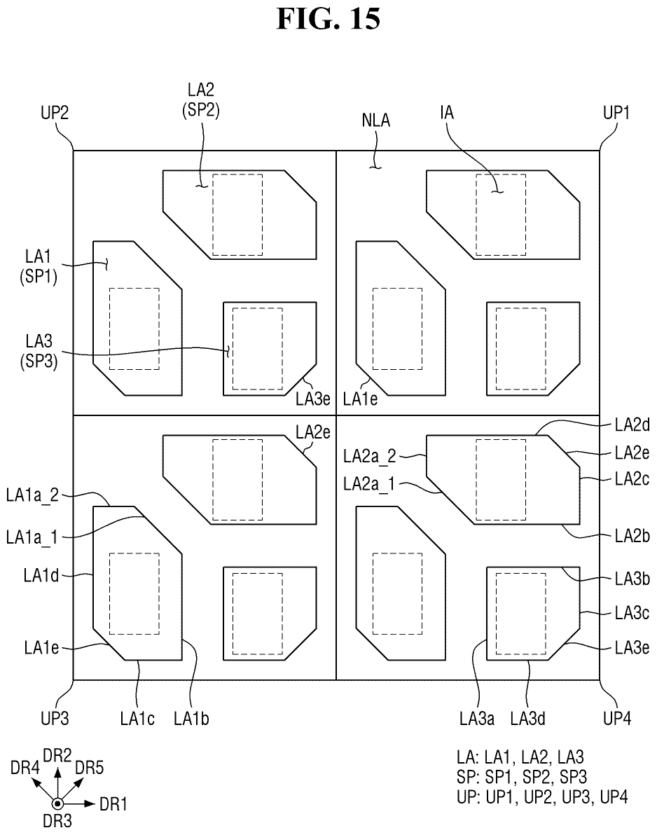

FIG. 15 is a plan view showing disposition of emission areas included in unit pixels according to an embodiment.

Referring to FIG. 15, the display device 10 according to the present embodiment is different from the display device 10 according to the embodiments described above with reference to FIGS. 10 to 14, in that the first to third emission areas LA1, LA2, and LA3 include third to fifth chamfered sides LA1e, LA2e, and LA3e, respectively.

More specifically, the first emission area LA1 may include the third chamfered side LA1e. The second emission area LA2 may include the fourth chamfered side LA2e. The third emission area LA3 may include the fifth chamfered side LA3e.

The third chamfered side LA1e may be positioned between the third side LA1c and the fourth side LA1d. The fourth chamfered side LA2e may be positioned between the seventh side LA2c and the eighth side LA2d. The fifth chamfered side LA3e may be positioned between the eleventh side LA3c and the twelfth side LA3d.

The extension direction of the fifth chamfered side LA3e may be different from the extension directions of the third chamfered side LA1e and the fourth chamfered side LA2e. The fifth chamfered side LA3e may extend in the fifth direction DR5, and the third chamfered side LA1e and the fourth chamfered side LA2e may extend in the fourth direction DR4.

However, the present disclosure is not limited thereto, and the third chamfered side LA1e, the fourth chamfered side LA2e, and the fifth chamfered side LA3e may extend in directions different from the first to fifth directions DR1, DR2, DR3, DR4, and DR5. In some embodiments, the extension directions of the third chamfered side LA1e and the fourth chamfered side LA2e may also be different from each other.

The display device 10 according to the present embodiment may prevent color mixing between the adjacent unit pixels UP by including the third to fifth chamfered sides LA1e, LA2e, and LA3e. For example, the separation distances between the first emission area LA1 of the first unit pixel UP1, the third emission area LA3 of the second unit pixel UP2, and the second emission area LA2 of the third unit pixel UP3 may be increased due to the third chamfered side LA1e, the fifth chamfered side LA3e, and the fourth chamfered side LA2e, respectively. Accordingly, color mixing between the adjacent unit pixels UP may be prevented.

In concluding the detailed description, those skilled in the art will appreciate that many variations and modifications can be made to the embodiments presented herein without substantially departing from the principles of the present disclosure. Therefore, the disclosed embodiments are used in a generic and descriptive sense only and not for purposes of limitation.

What is claimed is:

1. A display device comprising:
a substrate; and
a light emitting element disposed on the substrate,
wherein the light emitting element comprises first to third emission areas spaced apart from one another,
the first emission area comprises a first portion overlapping the third emission area in a first direction, and a second portion overlapping the second emission area in the first direction,
the second emission area comprises a third portion overlapping the third emission area in a second direction different from the first direction, and a fourth portion overlapping the first emission area in the second direction, and
a first side of the second portion and a second side of the fourth portion extend in a third direction different from the first direction and the second direction.

2. The display device of claim 1, wherein
the first portion comprises a third side facing the third emission area,
the third portion comprises a fourth side facing the third emission area,
the third side extends in the second direction, and
the fourth side extends in the first direction.

3. The display device of claim 2, wherein
the third emission area comprises a fifth side opposing the third side, and a sixth side opposing the fourth side, and
the fifth side extends in the second direction, and the sixth side extends in the first direction.

4. The display device of claim 3, wherein
an angle formed by the first side and the third side is an obtuse angle,
an angle formed by the second side and the fourth side is an obtuse angle, and
an angle formed by the fifth side and the sixth side is a right angle.

5. The display device of claim 4, wherein a length of the third side in the second direction is longer than a length of the fifth side in the second direction.

6. The display device of claim 5, wherein a length of the fourth side in the first direction is longer than a length of the sixth side in the first direction.

7. The display device of claim 1, wherein
the first emission area and the second emission area have a trapezoidal shape, and
the third emission area has a rectangular shape.

8. The display device of claim 7, wherein
the first portion and the third portion have a rectangular shape, and
the second portion and the fourth portion have a triangular shape.

9. The display device of claim 1, wherein
the first to third emission areas respectively comprise first to third vertices located at positions at which the first to third emission areas face each other, and
with respect to a first reference line extending in the third direction from a center of a reference circle passing through the first to third vertices, the first emission area and the second emission area are spaced apart by a same distance.

10. The display device of claim 9, wherein a distance between the first emission area and a second reference line extending in the second direction from the center of the reference circle is greater than a distance between the second reference line and the third emission area.

11. The display device of claim 10, wherein a distance between the second emission area and a third reference line extending in the first direction from the center of the reference circle and is greater than a distance between the third reference line and the third emission area.

12. The display device of claim 1, further comprising a pixel defining film comprising an opening defining the first to third emission areas, wherein
the light emitting element comprises a light emitting layer disposed in the opening, and
the light emitting layer contains an ink material.

13. The display device of claim 12, wherein a width of a landing area of the ink material is smaller than or equal to a width of each of the first to third emission areas.

14. The display device of claim 1, further comprising:
a plurality of color filters disposed on the light emitting element, and overlapping the first to third emission areas; and
a light transmitting layer disposed between the light emitting element and the color filter, overlapping the first to third emission areas, and containing a light scatterer.

15. A display device comprising a first unit pixel and a second unit pixel,
wherein each of the first unit pixel and the second unit pixel comprises:
first to third emission areas comprising a light emitting element and spaced apart from each other; and
a light blocking area surrounding the first to third emission areas,
wherein the first emission area comprises a first portion overlapping the third emission area in a first direction, and a second portion overlapping the second emission area in the first direction,
the second emission area comprises a third portion overlapping the third emission area in a second direction different from the first direction, and a fourth portion overlapping the first emission area in the second direction, and
a first light blocking area located between the second portion and the fourth portion extends in a third direction different from the first direction and the second direction.

16. The display device of claim 15, wherein a second light blocking area located between the first portion and the third emission area extends in the second direction, and a third light blocking area located between the third portion and the third emission area extends in the first direction.

17. The display device of claim 16, wherein
an angle formed by an extension direction of the first light blocking area and an extension direction of the second light blocking area is an obtuse angle,
an angle formed by the extension direction of the first light blocking area and an extension direction of the third light blocking area is an obtuse angle, and
an angle formed by the extension direction of the second light blocking area and the extension direction of the third light blocking area is a right angle.

18. The display device of claim 16, wherein
the first to third emission areas respectively comprise first to third vertices located at positions at which the first to third emission areas face each other, and
with respect to a first reference line extending in the third direction from a center of a reference circle passing through the first to third vertices, a width of one area of the first light blocking area and a width of another area of the first light blocking area are the same.

19. The display device of claim 18, wherein with respect to a second reference line extending in the second direction from the center of the reference circle, a width of one area of the second light blocking area is greater than a width of another area of the second light blocking area.

20. The display device of claim 19, wherein with respect to a first reference line extending in the first direction from the center of the reference circle, a width of one area of the third light blocking area is greater than a width of another area of the third light blocking area.

21. The display device of claim 16, further comprising a third unit pixel, wherein
the second unit pixel is disposed on one side of the first unit pixel in the first direction, the third unit pixel is disposed on one side of the first unit pixel in the second direction, and
a width of a fourth emission area located between the second emission area and the third emission area of the first unit pixel and the first emission area of the second unit pixel is equal to a width of a fifth light blocking area located between the first emission area and the third emission area of the first unit pixel and the second emission area of the third unit pixel.

22. The display device of claim 21, wherein the first to fifth light blocking areas have a same width.

23. The display device of claim 15, wherein
the first emission area and the second emission area have a trapezoidal shape, and
the third emission area has a rectangular shape.

24. The display device of claim 23, wherein
the first portion and the third portion have a rectangular shape, and
the second portion and the fourth portion have a triangular shape.

25. A display device comprising first to third emission areas spaced apart from each other, wherein
the first emission area comprises a first side facing the second emission area, a second side facing the third emission area, a third side opposing the first side, and a fourth side opposing the second side,
the second emission area comprises a fifth side facing the first emission area, a sixth side facing the third emission area, a seventh side opposing the fifth side, and an eighth side opposing the sixth side,
the third emission area comprises a ninth side opposing the second side, a tenth side opposing the sixth side, an eleventh side opposing the ninth side, and a twelfth side opposing the tenth side,
the third side, the sixth side, the eighth side, the tenth side, and the twelfth side extend in a first direction,
the second side, the fourth side, the seventh side, the ninth side, and the eleventh side extend in a second direction different from the first direction, and
the first side and the fifth side extend in a third direction different from the first direction and the second direction.

26. The display device of claim 25, wherein
the first emission area comprises a first chamfered side located between the first side and the fourth side, and
the second emission area comprises a second chamfered side located between the fifth side and the eighth side.

27. The display device of claim 26, wherein the first chamfered side extends in the first direction, and the second chamfered side extends in the second direction.

28. The display device of claim 26, wherein the first chamfered side and the second chamfered side extend in a direction different from the first to third directions.

29. The display device of claim 26, wherein
the first emission area comprises a third chamfered side located between the third side and the fourth side,
the second emission area comprises a fourth chamfered side located between the seventh side and the eighth side, and
the third emission area comprises a fifth chamfered side located between the eleventh side and the twelfth side.

30. The display device of claim 25, wherein
the first emission area comprises a third chamfered side located between the third side and the fourth side,
the second emission area comprises a fourth chamfered side located between the seventh side and the eighth side, and
the third emission area comprises a fifth chamfered side located between the eleventh side and the twelfth side.

31. The display device of claim 30, wherein an extension direction of the fifth chamfered side is different from extension directions of the third chamfered side and the fourth chamfered side.

32. The display device of claim 31, wherein the third chamfered side and the fourth chamfered side extend in the third direction.

33. The display device of claim 31, wherein the third to fifth chamfered sides extend in a direction different from the first to third directions.
